(19) United States
(12) Patent Application Publication
(10) Pub. No.: US 2026/0092970 A1
(43) Pub. Date: Apr. 2, 2026

(54) METHOD OF USING A TEST PATTERN FOR TESTING FUNCTIONALITIES OF EXTERNAL DEVICES WHEN AN ITEM IS ATTACHED TO A VEHICLE

(71) Applicant: Volvo Car Corporation, Göteborg (SE)

(72) Inventors: Victor GUSTAFSON, Göteborg (SE); Henrik KLARS, Göteborg (SE); Michael ZACH, Göteborg (SE); Magnus AXELSSON, Göteborg (SE)

(73) Assignee: Volvo Car Corporation, Göteborg (SE)

(21) Appl. No.: 18/899,481

(22) Filed: Sep. 27, 2024

(51) Int. Cl. G01R 31/3183; G01R 31/319; G01R 31/3193

(52) U.S. Cl. CPC G01R 31/318307; G01R 31/318371; G01R 31/31905; G01R 31/31935

(57) ABSTRACT

Embodiments relate to a system and method of using a test pattern for testing functionalities of external devices when an item is attached to a vehicle. The method includes identifying an item mechanically coupled to a vehicle, establishing a first connection via a communication module, with the item, generating a test pattern for testing a device from a plurality of devices, wherein the device is at least one of part of the vehicle, and part of the item and determining control of the device. The method further includes actuating the device to verify a functionality of the device based on the test pattern.

### FIELD OF INVENTION

This disclosure relates to the field of vehicle-to-everything communication. The disclosure is more particularly related to the method of using a test pattern for testing functionalities of external devices when an item is attached to a vehicle.

### BACKGROUND

A vehicle may include components such as cameras, that may be used for various purposes. In the current systems, there is no efficient way to verify if the components are in proper working condition when an item (e.g., a trailer) is attached to the vehicle.

Therefore, there is a need for a method of using a test pattern for testing functionalities of external devices when an item is attached to a vehicle.

### SUMMARY

The following presents a summary to provide a basic understanding of one or more embodiments described herein. This summary is not intended to identify key or critical elements or delineate any scope of the different embodiments and/or any scope of the claims. The sole purpose of the summary is to present some concepts in a simplified form as a prelude to the more detailed description presented herein.

In an aspect, the present disclosure relates to a system comprising a communication module, and a processor storing instructions in a non-transitory memory that, when executed, cause the processor to: identify an item mechanically coupled to a vehicle, establish a first connection, via the communication module, with the item, generate a test pattern for testing a device from a plurality of devices, wherein the device is at least one of part of the vehicle, and part of the item, determine control of the device, and actuate the device to verify a functionality of the device based on the test pattern.

In another aspect, the present disclosure relates to a method comprising determining an item mechanically coupled to a vehicle, establishing a first connection via a communication module, with the item, generating a test pattern for testing a device from a plurality of devices, wherein the device is at least one of part of the vehicle, and part of the item, determining control of the device, and actuating the device to verify a functionality of the device based on the test pattern.

In another aspect, the present disclosure relates to a non-transitory computer-readable medium having stored thereon instructions executable by a computer system to perform operations comprising determining an item mechanically coupled to a vehicle, establishing a first connection via a communication module, with the item, generating a test pattern for testing a device from a plurality of devices, wherein the device is at least one of part of the vehicle, and part of the item, determining control of the device, and actuating the device to verify a functionality of the device based on the test pattern.

### BRIEF DESCRIPTION OF THE FIGURES

These and other aspects of the present invention will now be described in more detail, with reference to the appended drawings showing exemplary embodiments of the present invention, in which:

FIG. 1 illustrates a block diagram of a system for assisting a driver when an item is attached to the vehicle according to an embodiment.

FIG. 2 illustrates a block diagram of electronic components of the vehicle according to an embodiment.

FIG. 3 illustrates a flow chart describing a method of assisting a driver when an item is attached to the vehicle according to an embodiment.

FIG. 4 illustrates steps executed by a system according to an embodiment.

FIG. 5 illustrates a block diagram of the method executed by the non-transitory computer-readable medium according to an embodiment.

FIG. 6A shows obtaining item or attachment details from the item itself according to an embodiment.

FIG. 6B shows obtaining item or attachment details from the cloud network according to an embodiment.

FIG. 6C shows detecting an attachment or trailer using wireless communication according to an embodiment.

FIG. 7A illustrates a message flow diagram between the vehicle and the device according to an embodiment.

FIG. 7B shows an example communication message format and memory allocation according to an embodiment.

FIG. 7C shows an example message exchange between trailer and the vehicle according to an embodiment.

FIG. 8 illustrates a flow chart describing a method of actuating a device according to an embodiment.

FIG. 9 illustrates steps executed by a system of actuating a device according to an embodiment.

FIG. 10 illustrates a block diagram of the method executed by the non-transitory computer-readable medium according to an embodiment.

FIG. 11 illustrates a flow chart describing a method of actuating a device according to an embodiment

FIG. 12 illustrates steps executed by a system of actuating a device according to an embodiment.

FIG. 13 illustrates a block diagram of the method executed by the non-transitory computer-readable medium according to an embodiment.

FIG. 14 illustrates an example block diagram for an Artificial Intelligence and Machine Learning (AI/ML) model used in a system according to an embodiment

FIG. 15A illustrates a structure of the neural network/machine learning model with a feedback loop according to an embodiment.

FIG. 15B illustrates a structure of the neural network/machine learning model with reinforcement learning according to an embodiment.

FIG. 16A illustrates a block diagram of the cyber security module in view of the system and server according to an embodiment.

FIG. 16B illustrates a block diagram of the cyber security module according to an embodiment.

FIG. 16C illustrates another block diagram of the cyber security module according to an embodiment.

### DETAILED DESCRIPTION

For simplicity and clarity of illustration, the drawing figures illustrate the general manner of construction, and descriptions and details of well-known features and techniques may be omitted to avoid unnecessarily obscuring the present disclosure. Additionally, elements in the drawing figures are not necessarily drawn to scale. For example, the dimensions of some of the elements in the figures may be exaggerated relative to other elements to help improve understanding of embodiments of the present disclosure. The same reference numerals in different figures denote the same elements.

Although the detailed description herein contains many specifics for the purpose of illustration, a person of ordinary skill in the art will appreciate that many variations and alterations to the details are considered to be included herein.

Accordingly, the embodiments herein are without any loss of generality to, and without imposing limitations upon, any claims set forth. The terminology used herein is for the purpose of describing particular embodiments only and is not limiting. Unless defined otherwise, all technical and scientific terms used herein have the same meaning as commonly understood by one with ordinary skill in the art to which this disclosure belongs. The following terms and phrases, unless otherwise indicated, shall be understood to have the following meanings.

As used herein, the articles “a” and “an” used herein refer to one or to more than one (i.e., to at least one) of the grammatical object of the article. By way of example, “an element” means one element or more than one element. Moreover, usage of articles “a” and “an” in the subject specification and annexed drawings construe to mean “one or more” unless specified otherwise or clear from context to mean a singular form.

As used herein, the terms “example” and/or “exemplary” mean serving as an example, instance, or illustration. For the avoidance of doubt, such examples do not limit the herein described subject matter. In addition, any aspect or design described herein as an “example” and/or “exemplary” is not necessarily preferred or advantageous over other aspects or designs, nor does it preclude equivalent exemplary structures and techniques known to those of ordinary skill in the art.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments described herein are, for example, capable of operation in sequences other than those illustrated or otherwise described herein. Furthermore, the terms “include,” and “have,” and any variations thereof, are intended to cover a non-exclusive inclusion, such that a process, method, system, article, device, or apparatus that comprises a list of elements is not necessarily limited to those elements, but may include other elements not expressly listed or inherent to such process, method, system, article, device, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the apparatus, methods, and/or articles of manufacture described herein are, for example, capable of operation in other orientations than those illustrated or otherwise described herein.

No element, act, or instruction used herein should be construed as critical or essential unless explicitly described as such. Also, as used herein, the articles “a” and “an” are intended to include items, and may be used interchangeably with “one or more. ” Furthermore, as used herein, the term “set” is intended to include items (e.g., related items, unrelated items, a combination of related items, and unrelated items, etc.), and may be used interchangeably with “one or more. ” Where only one item is intended, the term “one” or similar language is used. Also, as used herein, the terms “has,” “have,” “having,” or the like are intended to be open-ended terms. Further, the phrase “based on” is intended to mean “based, at least in part, on” unless explicitly stated otherwise.

The terms “couple,” “coupled,” “couples,” “coupling,” and the like should be broadly understood and refer to connecting two or more elements mechanically and/or otherwise. Two or more electrical elements may be electrically coupled together, but not be mechanically or otherwise coupled together. Coupling may be for any length of time, e.g., permanent or semi-permanent or only for an instant. “Electrical coupling” and the like should be broadly understood and include electrical coupling of all types. The absence of the word “removably,” “removable,” and the like near the word “coupled,” and the like does not mean that the coupling, etc. in question is or is not removable.

As used herein, two or more elements or modules are “integral” or “integrated” if they operate functionally together. Two or more elements are “non-integral” if each element can operate functionally independently.

As defined herein, “real-time” can, in some embodiments, be defined with respect to operations carried out as soon as practically possible upon occurrence of a triggering event. A triggering event can include receipt of data necessary to execute a task or to otherwise process information. Because of delays inherent in transmission and/or in computing speeds, the term “real time” encompasses operations that occur in “near” real time or somewhat delayed from a triggering event. In a number of embodiments, “real time” can mean real time less a time delay for processing (e.g., determining) and/or transmitting data. The particular time delay can vary depending on the type and/or amount of the data, the processing speeds of the hardware, the transmission capability of the communication hardware, the transmission distance, etc. However, in many embodiments, the time delay can be less than approximately one second, two seconds, five seconds, or ten seconds.

As used herein, the term “approximately” can mean within a specified or unspecified range of the specified or unspecified stated value. In some embodiments, “approximately” can mean within plus or minus ten percent of the stated value. In other embodiments, “approximately” can mean within plus or minus five percent of the stated value. In further embodiments, “approximately” can mean within plus or minus three percent of the stated value. In yet other embodiments, “approximately” can mean within plus or minus one percent of the stated value.

As used herein the term “component” refers to a distinct and identifiable part, element, or unit within a larger system, structure, or entity. It is a building block that serves a specific function or purpose within a more complex whole. Components are often designed to be modular and interchangeable, allowing them to be combined or replaced in various configurations to create or modify systems. Components may be a combination of mechanical, electrical, hardware, firmware, software and/or other engineering elements.

Digital electronic circuitry, or computer software, firmware, or hardware, including the structures disclosed in this specification and their structural equivalents, or in combinations of one or more of them may realize the implementations and all of the functional operations described in this specification. Implementations may be as one or more computer program products i.e., one or more modules of computer program instructions encoded on a computer-readable medium for execution by, or to control the operation of, data processing apparatus. The computer-readable medium may be a machine-readable storage device, a machine-readable storage substrate, a memory device, a composition of matter affecting a machine-readable propagated signal, or a combination of one or more of them. The term “computing system” encompasses all apparatus, devices, and machines for processing data, including by way of example, a programmable processor, a computer, or multiple processors or computers. The apparatus may include, in addition to hardware, code that creates an execution environment for the computer program in question, e.g., code that constitutes processor firmware, a protocol stack, a database management system, an operating system, or a combination of one or more of them. A propagated signal is an artificially generated signal (e.g., a machine-generated electrical, optical, or electromagnetic signal) that encodes information for transmission to a suitable receiver apparatus.

The actual specialized control hardware or software code used to implement these systems and/or methods is not limiting to the implementations. Thus, any software and any hardware can implement the systems and/or methods based on the description herein without reference to specific software code.

A computer program (also known as a program, software, software application, script, or code) is written in any appropriate form of programming language, including compiled or interpreted languages. Any appropriate form, including a standalone program or a module, component, subroutine, or other unit suitable for use in a computing environment may deploy it. A computer program does not necessarily correspond to a file in a file system. A program may be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program may execute on one computer or on multiple computers that are located at one site or distributed across multiple sites and interconnected by a communication network.

One or more programmable processors, executing one or more computer programs to perform functions by operating on input data and generating output, perform the processes and logic flows described in this specification. The processes and logic flows may also be performed by, and apparatus may also be implemented as, special purpose logic circuitry, for example, without limitation, a Field Programmable Gate Array (FPGA), an Application Specific Integrated Circuit (ASIC), Application Specific Standard Products (ASSPs), System-On-a-Chip (SOC) systems, Complex Programmable Logic Devices (CPLDs), etc.

Processors suitable for the execution of a computer program include, by way of example, both general and special purpose microprocessors, and any one or more processors of any appropriate kind of digital computer. A processor will receive instructions and data from a read-only memory or a random-access memory or both. Elements of a computer can include a processor for performing instructions and one or more memory devices for storing instructions and data. A computer will also include, or is operatively coupled to receive data, transfer data or both, to/from one or more mass storage devices for storing data e.g., magnetic disks, magneto optical disks, optical disks, or solid-state disks. However, a computer need not have such devices. Moreover, another device, e.g., a mobile telephone, a personal digital assistant (PDA), a mobile audio player, a Global Positioning System (GPS) receiver, etc. may embed a computer. Computer-readable media suitable for storing computer program instructions and data include all forms of non-volatile memory, media and memory devices, including, by way of example, semiconductor memory devices (e.g., Erasable Programmable Read-Only Memory (EPROM), Electronically Erasable Programmable Read-Only Memory (EEPROM), and flash memory devices), magnetic disks (e.g., internal hard disks or removable disks), magneto optical disks (e.g. Compact Disc Read-Only Memory (CD ROM) disks, Digital Versatile Disk-Read-Only Memory (DVD-ROM) disks) and solid-state disks. Special purpose logic circuitry may supplement or incorporate the processor and the memory.

To provide for interaction with a user, a computer may have a display device, e.g., a Cathode Ray Tube (CRT) or Liquid Crystal Display (LCD) monitor, for displaying information to the user, and a keyboard and a pointing device, e.g., a mouse or a trackball, by which the user may provide input to the computer. Other kinds of devices provide for interaction with a user as well. For example, feedback to the user may be any appropriate form of sensory feedback, e.g., visual feedback, auditory feedback, or tactile feedback; and a computer may receive input from the user in any appropriate form, including acoustic, speech, or tactile input.

A computing system that includes a back-end component, e.g., a data server, or that includes a middleware component, e.g., an application server, or that includes a front-end component, e.g., a client computer having a graphical user interface or a Web browser through which a user may interact with an implementation, or any appropriate combination of one or more such back-end, middleware, or front-end components, may realize implementations described herein. Any appropriate form or medium of digital data communication, e.g., a communication network may interconnect the components of the system. Examples of communication networks include a Local Area Network (LAN) and a Wide Area Network (WAN), e.g., Intranet and Internet.

The computing system may include clients and servers. A client and server are remote from each other and typically interact through a communication network. The relationship of the client and server arises by virtue of computer programs running on the respective computers and having a client-server relationship with each other.

Embodiments of the present invention may comprise or utilize a special purpose or general purpose computer including computer hardware. Embodiments within the scope of the present invention may also include physical and other computer-readable media for carrying or storing computer-executable instructions and/or data structures. Such computer-readable media can be any media accessible by a general purpose or special purpose computer system. Computer-readable media that store computer-executable instructions are physical storage media. Computer-readable media that carry computer-executable instructions are transmission media. Thus, by way of example and not limitation, embodiments of the invention can comprise at least two distinct kinds of computer-readable media: physical computer-readable storage media and transmission computer-readable media.

Although the present embodiments described herein are with reference to specific example embodiments it will be evident that various modifications and changes may be made to these embodiments without departing from the broader spirit and scope of the various embodiments. For example, hardware circuitry (e.g., Complementary Metal Oxide Semiconductor (CMOS) based logic circuitry), firmware, software (e.g., embodied in a non-transitory machine-readable medium), or any combination of hardware, firmware, and software may enable and operate the various devices, units, and modules described herein. For example, transistors, logic gates, and electrical circuits (e.g., Application Specific Integrated Circuit (ASIC) and/or Digital Signal Processor (DSP) circuit) may embody the various electrical structures and methods.

In addition, a non-transitory machine-readable medium and/or a system may embody the various operations, processes, and methods disclosed herein. Accordingly, the specification and drawings are illustrative rather than restrictive.

Physical computer-readable storage media includes RAM, ROM, EEPROM, CD-ROM or other optical disk storage (such as CDs, DVDs, etc.), magnetic disk storage or other magnetic storage devices, solid-state disks or any other medium. They store desired program code in the form of computer-executable instructions or data structures which can be accessed by a general purpose or special purpose computer.

As used herein, the term “network” refers to one or more data links that enable the transport of electronic data between computer systems and/or modules and/or other electronic devices. When a network or another communications connection (either hardwired, wireless, or a combination of hardwired or wireless) transfers or provides information to a computer, the computer properly views the connection as a transmission medium. A general purpose or special purpose computer access transmission media that can include a network and/or data links which carry desired program code in the form of computer-executable instructions or data structures. The scope of computer-readable media includes combinations of the above, that enable the transport of electronic data between computer systems and/or modules and/or other electronic devices. The term network may include the Internet, a local area network, a wide area network, or combinations thereof. The network may include one or more networks or communication systems, such as the Internet, the telephone system, satellite networks, cable television networks, and various other private and public networks. In addition, the connections may include wired connections (such as wires, cables, fiber optic lines, etc.), wireless connections, or combinations thereof. Furthermore, although not shown, other computers, systems, devices, and networks may also be connected to the network. Network refers to any set of devices or subsystems connected by links joining (directly or indirectly) a set of terminal nodes sharing resources located on or provided by network nodes. The computers use common communication protocols over digital interconnections to communicate with each other. For example, subsystems may comprise the cloud. Cloud refers to servers that are accessed over the Internet, and the software and databases that run on those servers.

Further, upon reaching various computer system components, program code in the form of computer-executable instructions or data structures can be transferred automatically from transmission computer-readable media to physical computer-readable storage media (or vice versa). For example, computer-executable instructions or data structures received over a network or data link can be buffered in RAM within a Network Interface Controller (NIC), and then eventually transferred to computer system RAM and/or to less volatile computer-readable physical storage media at a computer system. Thus, computer system components that also (or even primarily) utilize transmission media may include computer-readable physical storage media.

Computer-executable instructions comprise, for example, instructions and data which cause a general purpose computer, special purpose computer, or special purpose processing device to perform a certain function or group of functions. The computer-executable instructions may be, for example, binary, intermediate format instructions such as assembly language, or even source code. Although the subject matter herein described is in a language specific to structural features and/or methodological acts, the described features or acts described do not limit the subject matter defined in the claims. Rather, the herein described features and acts are example forms of implementing the claims.

While this specification contains many specifics, these do not construe as limitations on the scope of the disclosure or of the claims, but as descriptions of features specific to particular implementations. A single implementation may implement certain features described in this specification in the context of separate implementations. Conversely, multiple implementations separately or in any suitable sub-combination may implement various features described herein in the context of a single implementation. Moreover, although features described herein as acting in certain combinations and even initially claimed as such, one or more features from a claimed combination may in some cases be excised from the combination, and the claimed combination may be directed to a sub-combination or variation of a sub-combination.

Similarly, while operations depicted herein in the drawings in a particular order to achieve desired results, this should not be understood as requiring that such operations be performed in the particular order shown or in sequential order or that all illustrated operations be performed, to achieve desirable results. In certain circumstances, multitasking and parallel processing may be advantageous. Moreover, the separation of various system components in the implementations should not be understood as requiring such separation in all implementations, and it should be understood that the described program components and systems may be integrated together in a single software product or packaged into multiple software products.

Even though particular combinations of features are recited in the claims and/or disclosed in the specification, these combinations are not intended to limit the disclosure of possible implementations. Other implementations are within the scope of the claims. For example, the actions recited in the claims may be performed in a different order and still achieve desirable results. In fact, many of these features may be combined in ways not specifically recited in the claims and/or disclosed in the specification. Although each dependent claim may directly depend on only one claim, the disclosure of possible implementations includes each dependent claim in combination with every other claim in the claim set.

Further, a computer system including one or more processors and computer-readable media such as computer memory may practice the methods. In particular, one or more processors execute computer-executable instructions, stored in the computer memory, to perform various functions such as the acts recited in the embodiments.

Those skilled in the art will appreciate that the invention may be practiced in network computing environments with many types of computer system configurations including personal computers, desktop computers, laptop computers, message processors, hand-held devices, multi-processor systems, microprocessor-based or programmable consumer electronics, network PCs, minicomputers, mainframe computers, mobile telephones, PDAs, pagers, routers, switches, etc. Distributed system environments where local and remote computer systems, which are linked (either by hardwired data links, wireless data links, or by a combination of hardwired and wireless data links) through a network, both perform tasks may also practice the invention. In a distributed system environment, program modules may be located in both local and remote memory storage devices.

As used herein, the term “Unauthorized access” is when someone gains access to a website, program, server, service, or other system using someone else's account or other methods. For example, if someone kept guessing a password or username for an account that was not theirs until they gained access, it is considered unauthorized access.

As used herein, the term “IoT” stands for Internet of Things which describes the network of physical objects “things” or objects embedded with sensors, software, and other technologies for the purpose of connecting and exchanging data with other devices and systems over the internet.

As used herein “Machine learning” refers to algorithms that give a computer the ability to learn without explicit programming, including algorithms that learn from and make predictions about data. Machine learning techniques include, but are not limited to, support vector machine, artificial neural network (ANN) (also referred to herein as a “neural net”), deep learning neural network, logistic regression, discriminant analysis, random forest, linear regression, rules-based machine learning, Naive Bayes, nearest neighbor, decision tree, decision tree learning, and hidden Markov, etc. For the purposes of clarity, part of a machine learning process can use algorithms such as linear regression or logistic regression. However, using linear regression or another algorithm as part of a machine learning process is distinct from performing a statistical analysis such as regression with a spreadsheet program. The machine learning process can continually learn and adjust the classifier as new data becomes available and does not rely on explicit or rules-based programming. The ANN may be featured with a feedback loop to adjust the system output dynamically as it learns from the new data as it becomes available. In machine learning, backpropagation and feedback loops are used to train the Artificial Intelligence/Machine Learning (AI/ML) model improving the model's accuracy and performance over time. Statistical modeling relies on finding relationships between variables (e.g., mathematical equations) to predict an outcome.

As used herein, the term “Data mining” is a process used to turn raw data into useful information. It is the process of analyzing large datasets to uncover hidden patterns, relationships, and insights that can be useful for decision-making and prediction.

As used herein, the term “Data acquisition” is the process of sampling signals that measure real world physical conditions and converting the resulting samples into digital numeric values that a computer manipulates. Data acquisition systems typically convert analog waveforms into digital values for processing. The components of data acquisition systems include sensors to convert physical parameters to electrical signals, signal conditioning circuitry to convert sensor signals into a form that can be converted to digital values, and analog-to-digital converters to convert conditioned sensor signals to digital values. Stand-alone data acquisition systems are often called data loggers.

As used herein, the term “Dashboard” is a type of interface that visualizes particular Key Performance Indicators (KPIs) for a specific goal or process. It is based on data visualization and infographics.

As used herein, a “Database” is a collection of organized information so that it can be easily accessed, managed, and updated. Computer databases typically contain aggregations of data records or files.

As used herein, the term “Data set” (or “Dataset”) is a collection of data. In the case of tabular data, a data set corresponds to one or more database tables, where every column of a table represents a particular variable, and each row corresponds to a given record of the data set in question. The data set lists values for each of the variables, such as height and weight of an object, for each member of the data set. Each value is known as a datum. Data sets can also consist of a collection of documents or files.

As used herein, a “sensor” is a device that detects and measures physical properties from the surrounding environment and converts this information into electrical or digital signals for further processing. Sensors play a crucial role in collecting data for various applications across industries. Sensors may be made of electronic, mechanical, chemical, or other engineering components. Examples include sensors to measure temperature, pressure, humidity, proximity, light, acceleration, orientation etc.

The term “infotainment system” or “in-vehicle infotainment system” (IVI) as used herein refers to a combination of vehicle systems which are used to deliver entertainment and information. In an example, the information may be delivered to the driver and the passengers of a vehicle/occupants through audio/video interfaces, control elements like touch screen displays, button panel, voice commands, and more. Some of the main components of an in-vehicle infotainment systems are integrated head-unit, heads-up display, high-end Digital Signal Processors (DSPs), and Graphics Processing Units (GPUs) to support multiple displays, operating systems, Controller Area Network (CAN), Low-Voltage Differential Signaling (LVDS), and other network protocol support (as per the requirement), connectivity modules, automotive sensors integration, digital instrument cluster, etc.

The term “environment” or “surrounding” as used herein refers to surroundings and the space in which a vehicle is navigating. It refers to dynamic surroundings in which a vehicle is navigating which includes other vehicles, obstacles, pedestrians, lane boundaries, traffic signs and signals, speed limits, potholes, snow, water logging etc.

The term “autonomous mode” as used herein refers to an operating mode which is independent and unsupervised.

The term “vehicle” as used herein refers to a thing used for transporting people or goods. Automobiles, cars, trucks, buses, etc., are examples of vehicles. Further, the vehicle may include electric vehicles (EVs), hybrid electric vehicles (HEVs) such as, without limitations, full hybrid electric vehicles (FHEVs) and mild hybrid electric vehicles (MHEVs), battery electric vehicles (BEVs), and plug-in hybrid electric vehicles (PHEVs).

The term “autonomous vehicle” also referred to as self-driving vehicle, driverless vehicle, robotic vehicle as used herein refers to a vehicle incorporating vehicular automation, that is, a vehicle that can sense its environment and move safely with little or no human input. Self-driving vehicles combine a variety of sensors to perceive their surroundings, such as thermographic cameras, Radio Detection and Ranging (RADAR), Light Detection and Ranging (LIDAR), Sound Navigation and Ranging (SONAR), Global Positioning System (GPS), odometry and inertial measurement unit. Control systems are designed for the purpose of interpreting sensor information to identify appropriate navigation paths, as well as obstacles and relevant signage.

The term “communication module” or “communication unit” or “communication system” as used herein refers to a system which enables the information exchange between two points. The process of transmission and reception of information is called communication. The elements of communication include but are not limited to a transmitter of information, channel or medium of communication and a receiver of information.

The term “autonomous communication” as used herein comprises communication over a period with minimal supervision under different scenarios and is not solely or completely based on pre-coded scenarios or pre-coded rules or a predefined protocol. Autonomous communication, in general, happens in an independent and an unsupervised manner. In an embodiment, a communication module is enabled for autonomous communication.

The term “communication connection” or “communication network” as used herein refers to a communication link. It refers to a communication channel that connects two or more devices for the purpose of data transmission. It may refer to a physical transmission medium such as a wire, or to a logical connection over a multiplexed medium such as a radio channel in telecommunications and computer networks. A channel is used for the information transfer of, for example, a digital bit stream, from one or several senders to one or several receivers. A channel has a certain capacity for transmitting information, often measured by its bandwidth in Hertz (Hz) or its data rate in bits per second. For example, a Vehicle-to-Vehicle (V2V) communication may wirelessly exchange information about the speed, location and heading of surrounding vehicles. Similarly, a Vehicle-to-Grid (V2G) communication may exchange charge information and further transfer charge from the vehicle to the grid.

The term “communication” as used herein refers to the transmission of information and/or data from one point to another. Communication may be by means of electromagnetic waves. Communication is also a flow of information from one point, known as the source, to another, the receiver. Communication comprises one of the following: transmitting data, instructions, information or a combination of data, instructions, and information. Communication happens between any two communication systems or communicating units. The term communication, herein, includes systems that combine other more specific types of communication, such as: V2I (Vehicle-to-Infrastructure), V2N (Vehicle-to-Network), V2V (Vehicle-to-Vehicle), V2P (Vehicle-to-Pedestrian), V2D (Vehicle-to-Device), V2G (Vehicle-to-Grid), and Vehicle-to-Everything (V2X) communication.

The term “Vehicle-to-Vehicle (V2V) communication” refers to the technology that allows vehicles to broadcast and receive messages. The messages may be omni-directional messages, creating a 360-degree “awareness” of other vehicles in proximity. Vehicles may be equipped with appropriate software (or safety applications) that can use the messages from surrounding vehicles to determine potential crash threats as they develop.

The term “Vehicle-to-Everything (V2X) communication” as used herein refers to transmission of information from a vehicle to any entity that may affect the vehicle, and vice versa. Depending on the underlying technology employed, there are two types of V2X communication technologies: cellular networks and other technologies that support direct device-to-device communication (such as Dedicated Short-Range Communication (DSRC), Port Community System (PCS), Bluetooth®, Wi-Fi®, etc.).

The term “protocol” as used herein refers to a procedure required to initiate and maintain communication; a formal set of conventions governing the format and relative timing of message exchange between two communications terminals; a set of conventions that govern the interactions of processes, devices, and other components within a system; a set of signaling rules used to convey information or commands between boards connected to the bus; a set of signaling rules used to convey information between agents; a set of semantic and syntactic rules that determine the behavior of entities that interact; a set of rules and formats (semantic and syntactic) that determines the communication behavior of simulation applications; a set of conventions or rules that govern the interactions of processes or applications between communications terminals; a formal set of conventions governing the format and relative timing of message exchange between communications terminals; a set of semantic and syntactic rules that determine the behavior of functional units in achieving meaningful communication; a set of semantic and syntactic rules for exchanging information.

The term “communication protocol” as used herein refers to standardized communication between any two systems. An example communication protocol is a DSRC protocol. The DSRC protocol uses a specific frequency band (e.g., 5.9 GHz (Gigahertz)) and specific message formats (such as the Basic Safety Message, Signal Phase and Timing, and Roadside Alert) to enable communications between vehicles and infrastructure components, such as traffic signals and roadside sensors. DSRC is a standardized protocol, and its specifications are maintained by various organizations, including the Institute of Electrical and Electronics Engineers (IEEE) and Society of Automotive Engineers (SAE) International.

The term “bidirectional communication” as used herein refers to an exchange of data between two components. In an example, the first component can be a vehicle and the second component can be an infrastructure that is enabled by a system of hardware, software, and firmware. In an example, the second component can be another vehicle capable of receiving and transmitting information with the first vehicle.

The term “alert” or “alert signal” refers to a communication to attract attention. An alert may include visual, tactile, audible alert and a combination of these alerts to warn the user of the vehicle. These alerts allow receivers, such as drivers or occupants, the ability to react and respond quickly.

The term “in communication with” as used herein, refers to any coupling, connection, or interaction using signals to exchange information, message, instruction, command, and/or data, using any system, hardware, software, protocol, or format regardless of whether the exchange occurs wirelessly or over a wired connection.

The term “electronic control unit” (ECU), also known as an “electronic control module”, is usually a module that controls one or more subsystems. Herein, an ECU may be installed in a vehicle or other motor vehicle. It may refer to many ECUs, and can include but not limited to, Engine Control Module (ECM), Powertrain Control Module (PCM), Transmission Control Module (TCM), Brake Control Module (BCM) or Electronic Brake Control Module (EBCM), Central Control Module (CCM), Central Timing Module (CTM), General Electronic Module (GEM), Body Control Module (BCM), and Suspension Control Module (SCM). ECUs together are sometimes referred to collectively as the vehicles'computer or vehicles'central computer and may include separate computers. In an example, the electronic control unit can be an embedded system in automotive electronics. In another example, the electronic control unit is wirelessly coupled with automotive electronics.

The terms “non-transitory computer-readable medium” and “computer-readable medium” include a single medium or multiple media such as a centralized or distributed database, and/or associated caches and servers that store one or more sets of instructions. Further, the terms “non-transitory computer-readable medium” and “computer-readable medium” include any tangible medium that is capable of storing, encoding, or carrying a set of instructions for execution by a processor that, for example, when executed, cause a system to perform any one or more of the methods or operations disclosed herein. As used herein, the term “computer-readable medium” is expressly defined to include any type of computer-readable storage device and/or storage disk and to exclude propagating signals.

The term “Vehicle Data bus” as used herein represents the interface to the vehicle data bus (e.g., Controller Area Network (CAN), Local Interconnect Network (LIN), Ethernet/IP, FlexRay, and Media Oriented Systems Transport (MOST)) that may enable communication between the Vehicle on-board equipment (OBE) and other vehicle systems to support connected vehicle applications.

The term, “handshaking” refers to an exchange of predetermined signals between agents connected by a communications channel to assure each that it is connected to the other (and not to an imposter). This may also include the use of passwords and codes by an operator. Handshaking signals are transmitted back and forth over a communications network to establish a valid connection between two stations. A hardware handshake uses dedicated wires such as the request-to-send (RTS) and clear-to-send (CTS) lines in a Recommended Standard 232 (RS-232) serial transmission. A software handshake sends codes such as “synchronize” (SYN) and “acknowledge” (ACK) in a Transmission Control Protocol/Internet Protocol (TCP/IP) transmission.

The term “computer vision module” or “computer vision system” allows the vehicle to “see” and interpret the world around it. This system uses a combination of cameras, sensors, and other technologies such as Radio Detection and Ranging (RADAR), Light Detection and Ranging (LIDAR), Sound Navigation and Ranging (SONAR), Global Positioning System (GPS), and Machine learning algorithms, etc. to collect visual data about the vehicle's surroundings and to analyze that data in real-time. The computer vision system is designed to perform a range of tasks, including object detection, lane detection, and pedestrian recognition. It uses deep learning algorithms and other machine learning techniques to analyze visual data and make decisions about how to control the vehicle. For example, the computer vision system may use object detection algorithms to identify other vehicles, pedestrians, and obstacles in the vehicle's path. It can then use this information to calculate the vehicle's speed and direction, adjust its trajectory to avoid collisions, and apply the brakes or accelerate as needed. It allows the vehicle to navigate safely and efficiently in a variety of driving conditions.

As used herein, the term “driver” refers to such an occupant, even when that occupant is not actually driving the vehicle but is situated in the vehicle so as to be able to take over control and function as the driver of the vehicle when the vehicle control system hands over control to the occupant or driver or when the vehicle control system is not operating in an autonomous or semi-autonomous mode. The driver is also referred to as an operator of the vehicle.

The term “application server” refers to a server that hosts applications or software that delivers a business application through a communication protocol. An application server framework is a service layer model. It includes software components available to a software developer through an application programming interface. It is system software that resides between the operating system (OS) on one side, the external resources such as a database management system (DBMS), communications and Internet services on another side, and the users'applications on the third side.

The term “cyber security” as used herein refers to application of technologies, processes, and controls to protect systems, networks, programs, devices, and data from cyber-attacks.

The term “cyber security module” as used herein refers to a module comprising application of technologies, processes, and controls to protect systems, networks, programs, devices and data from cyber-attacks and threats. It aims to reduce the risk of cyber-attacks and protect against the unauthorized exploitation of systems, networks, and technologies. It includes, but is not limited to, critical infrastructure security, application security, network security, cloud security, Internet of Things (IoT) security.

The term “encrypt” used herein refers to securing digital data using one or more mathematical techniques, along with a password or “key” used to decrypt the information. It refers to converting information or data into a code, especially to prevent unauthorized access. It may also refer to concealing information or data by converting it into a code. It may also be referred to as cipher, code, encipher, encode. A simple example is representing alphabets with numbers—say, ‘A’ is ‘01’, ‘B’ is ‘02’, and so on. For example, a message like “HELLO” will be encrypted as “0805121215,”and this value will be transmitted over the network to the recipient(s).

The term “decrypt” used herein refers to the process of converting an encrypted message back to its original format. It is generally a reverse process of encryption. It decodes the encrypted information so that only an authorized user can decrypt the data because decryption requires a secret key or password. This term could be used to describe a method of unencrypting the data manually or unencrypting the data using the proper codes or keys.

The term “cyber security threat” used herein refers to any possible malicious attack that seeks to unlawfully access data, disrupt digital operations, or damage information. A malicious act includes but is not limited to damaging data, stealing data, or disrupting digital life in general. Cyber threats include, but are not limited to, malware, spyware, phishing attacks, ransomware, zero-day exploits, trojans, advanced persistent threats, wiper attacks, data manipulation, data destruction, rogue software, malvertising, unpatched software, computer viruses, man-in-the-middle attacks, data breaches, Denial of Service (DoS) attacks, and other attack vectors.

The term “hash value” used herein can be thought of as fingerprints for files. The contents of a file are processed through a cryptographic algorithm, and a unique numerical value, the hash value, is produced that identifies the contents of the file. If the contents are modified in any way, the value of the hash will also change significantly. Example algorithms used to produce hash values: the Message Digest-5 (MD5) algorithm and Secure Hash Algorithm-1 (SHA1).

The term “integrity check” as used herein refers to the checking for accuracy and consistency of system related files, data, etc. It may be performed using checking tools that can detect whether any critical system files have been changed, thus enabling the system administrator to look for unauthorized alteration of the system. For example, data integrity corresponds to the quality of data in the databases and to the level by which users examine data quality, integrity, and reliability. Data integrity checks verify that the data in the database is accurate, and functions as expected within a given application.

The term “alarm” as used herein refers to a trigger when a component in a system or the system fails or does not perform as expected. The system may enter an alarm state when a certain event occurs. An alarm indication signal is a visual signal to indicate the alarm state. For example, when a cyber security threat is detected, a system administrator may be alerted via sound alarm, a message, a glowing LED, a pop-up window, etc. Alarm indication signal may be reported downstream from a detecting device, to prevent adverse situations or cascading effects.

As used herein, the term “cryptographic protocol” is also known as security protocol or encryption protocol. It is an abstract or concrete protocol that performs a security-related function and applies cryptographic methods often as sequences of cryptographic primitives. A protocol describes how the algorithms should be used. A sufficiently detailed protocol includes details about data structures and representations, at which point it can be used to implement multiple, interoperable versions of a program. Cryptographic protocols are widely used for secure application-level data transport. A cryptographic protocol usually incorporates at least some of these aspects: key agreement or establishment, entity authentication, symmetric encryption, and message authentication material construction, secured application-level data transport, non-repudiation methods, secret sharing methods, and secure multi-party computation. Hashing algorithms may be used to verify the integrity of data. Secure Socket Layer (SSL) and Transport Layer Security (TLS), the successor to SSL, are cryptographic protocols that may be used by networking switches to secure data communications over a network.

The embodiments described herein can be directed to one or more of a system, a method, an apparatus, and/or a computer program product at any possible technical detail level of integration. The computer program product can include a computer-readable storage medium (or media) having computer-readable program instructions thereon for causing a processor to carry out aspects of the one or more embodiments described herein.

The flowcharts and block diagrams in the figures illustrate the architecture, functionality and/or operation of possible implementations of systems, computer-implementable methods and / or computer program products according to one or more embodiments described herein. In this regard, each block in the flowchart or block diagrams can represent a module, segment and/or portion of instructions, which comprises one or more executable instructions for implementing the specified logical function(s). In one or more alternative implementations, the functions noted in the blocks can occur out of the order noted in the Figures. For example, two blocks shown in succession can be executed substantially concurrently, and/or the blocks can sometimes be executed in the reverse order, depending upon the functionality involved. It will also be noted that each block of the block diagrams and/or flowchart illustration, and/or combinations of blocks in the block diagrams and/or flowchart illustration, can be implemented by special purpose hardware-based systems that can perform the specified functions and/or acts and/or carry out one or more combinations of special purpose hardware and/or computer instructions.

As used in this application, the terms “component,” “system,” “platform,” “interface,” and/or the like, can refer to and/or can include a computer-related entity or an entity related to an operational machine with one or more specific functionalities. The entities described herein can be either hardware, a combination of hardware and software, software, or software in execution. For example, a component can be, but is not limited to being, a process running on a processor, a processor, an object, an executable, a thread of execution, a program and/or a computer. By way of illustration, both an application running on a server and the server can be a component. One or more components can reside within a process and/or thread of execution and a component can be localized on one computer and/or distributed between two or more computers. In another example, respective components can execute from various computer-readable media having various data structures stored thereon. The components can communicate via local and/or remote processes such as in accordance with a signal having one or more data packets (e.g., data from one component interacting with another component in a local system, distributed system and/or across a network such as the Internet with other systems via the signal). As another example, a component can be an apparatus with specific functionality provided by mechanical parts operated by electric or electronic circuitry, which is operated by a software and/or firmware application executed by a processor. In such a case, the processor can be internal and/or external to the apparatus and can execute at least a part of the software and/or firmware application. As yet another example, a component can be an apparatus that provides specific functionality through electronic components without mechanical parts, where the electronic components can include a processor and/or other means to execute software and/or firmware that confers at least in part the functionality of the electronic components. In an aspect, a component can emulate an electronic component via a virtual machine, e.g., within a cloud computing system.

The embodiments described herein include mere examples of systems and computer-implemented methods. It is, of course, not possible to describe every conceivable combination of components and/or computer-implemented methods for purposes of describing the one or more embodiments, but one of ordinary skill in the art can recognize that many further combinations and/or permutations of the one or more embodiments are possible. Furthermore, to the extent that the terms “includes,” “has,” “possesses,” and the like are used in the detailed description, claims, appendices and/or drawings such terms are intended to be inclusive in a manner similar to the term “comprising” as “comprising” is interpreted when employed as a transitional word in a claim.

As used herein the term “monitoring” refers to systematic observation and assessment of a system, process, or environment in real-time or near real-time. It involves the regular collection, analysis, and interpretation of data using various sensors. Monitoring may be continuous or adaptive.

The term “vehicle system” or “computer system” or “system of a vehicle” as used herein refers to the vehicle comprising the system described in the current application. The system may be integrated and is a part of the vehicle, for example, a system executing a method on a processor storing instructions in a non-transitory memory of the computer system of the vehicle. The system may be external, but the instructions or method is executed through the vehicle, for example the method being in a cloud but is accessed and executed by the vehicle. The system may be designed for a specific purpose to carry out a certain function or task, for example, transmitting a specific message to a user device. The designed system comprising instructions may also be using existing systems present on the vehicle, for example, a communication system of the vehicle.

The term “battery” as used herein refers to a battery system in the vehicle, wherein the battery system may be used for starting the vehicle or may be used for operating the vehicle. The battery system may also be used to enable the vehicle to run.

The term “user” as used herein refers to any individual who is a driver or an owner of the vehicle. Broadly, it may encompass any individual having the possession of the vehicle.

The term “item” as used herein in reference to a vehicle encompasses a range of things or attachments that may be added to the vehicle. It may also include a separate, unpowered trailer that is connected to a motorized vehicle. Broadly, it can be referred to as anything that changes or affects the vehicle's range and/or vehicle's dimensions. Some of the examples could be cargo, trailers, bikes, boats, etc. Some of the accessories for the attachment facilitation can either be factory-installed by the manufacturer or added aftermarket by vehicle owners or professionals. Some common examples include roof racks for carrying extra cargo, towing hitches for hauling trailers, bike racks for bicycle transportation, and cargo carriers for carrying additional luggage and gear, etc. A trailer is any wheeled construction that is pulled by another vehicle. Some common trailer types include utility trailers, recreational vehicles (RV) or other automotive vehicles, house trailers, mobile homes, auto homes, truck trailers, auto carts, wagons, vans, containers, homes, caravans, tandem trailers, single-axle trailers, popup campers, travel trailers, livestock trailers, flatbed trailers, enclosed car haulers, and boat trailers, among others.

The term “malfunction” as used herein refers to a part or a component of the vehicle or the item that is not functioning properly. As an example, a malfunction may occur in at least one or more of a headlight display, a brake light display, a taillight display, a turn indicator display, a sensor, a door, a trunk, a tire, and visible emissions from exhaust of the vehicle.

The term “malfunction information” as used herein refers to details on the occurrence of a malfunction in a vehicle or the item.

The term “vehicle configuration” refers to the specific setup or arrangement of items in a vehicle, considering whether attachments or additional items are present or not and where they are present. This configuration can involve a variety of accessories and improvements intended to enhance the vehicle's functionality, appearance, and/or performance. These modifications may include factory-installed features by the manufacturer or aftermarket additions by vehicle owners or professionals. Examples of different vehicle configurations include having a trailer attached versus not having one, having a bike rack installed versus not having one, and having a bike secured in the bike rack versus not having a bike in the rack. Additionally, the location of the bike, such as on a luggage rack above the vehicle or on a bike rack behind the vehicle, is also considered in the vehicle configuration. The concept of vehicle configuration becomes relevant when changes affect the vehicle's range and/or vehicle's dimensions, indicating how and how much such alterations influence the vehicle's overall range and/or overall dimensions. A change in vehicle configuration is any change to the vehicle that impacts range or dimensions. A vehicle along with its attachment such as a trailer is also referred to as a vehicle combination.

The term “vehicle combination” or “vehicle item combination” refers to a set of vehicles that are interconnected or joined together for the purpose of transportation and/or towing. This combination may comprise different types of vehicles, such as a truck and trailer, or multiple trailers connected as a configuration. It may be used for transporting goods, materials, or people, and often requires specific regulations, licensing, and handling considerations based on the combination's size, weight, and type. For instance, common vehicle combinations include tractor-trailer trucks, buses towing trailers, or multiple trailers attached to a single towing vehicle.

The term “mechanically coupled” refers to components or systems that are physically connected or linked together in a way that allows them to transmit forces, motion, or energy.

The term “external to the vehicle” or “external to the vehicle item combination” refers to it as not part of the vehicle and not part of the item. The devices external to the vehicle refer to devices that are not part of the vehicle and devices that are not part of the item.

The term “safety zone” or “safe zone” or “contact free zone” of a vehicle refers to the area immediately surrounding a vehicle where extra caution and safety measures should be taken to avoid accidents or hazards. This zone may vary depending on the type of vehicle, its size, and the circumstances, but it generally extends a certain distance around the vehicle. Safe zones may include the space around the vehicle, to the front, sides, and rear, typically within a few feet or meters. This area varies depending on whether the vehicle is stationary or moving at low speeds, size of the vehicle, weight of the vehicle, whether the vehicle is changing lanes, speeding up, or overtaking other vehicles, in addition to considering any attachments forming a vehicle combination. Larger vehicles such as buses, trucks, or heavy machinery have larger safety zones due to their size and blind spots. These larger vehicles may often have specific blind spots or “no-zones” where the driver's visibility is limited. Determining the proper safety zone of a vehicle, and maintaining the same, ensures road safety and prevents accidents. The safety zone may be specified in feet or meters around the vehicle as a circular region or it can vary on each side of the vehicle. In an embodiment, the safety region could be a rectangular region. In another embodiment, the front safety zone region may be different to the back safety region, left side safety region may be different from right safety region, front safety region and back safety region, etc., depending on the vehicle combination, vehicle combination actions, and surroundings. The safety region may be adaptive, meaning the system may have the ability to adjust or modify the safety region in response to varying conditions, circumstances, or input. In an embodiment, the safety zone may be an adaptive smart safety zone. The system may determine an adaptive smart safety zone by utilizing active data from sensors and intelligent technologies and dynamically adjust the safety zone based on changing conditions.

The term “vehicle dynamics” as used herein refers to vehicle motion and vehicle maintaining traction when driving in adverse conditions. Vehicle dynamics may be used to predict and control the motion of the vehicle.

The term “nearby vehicle” or “neighboring vehicle” or “surrounding vehicle” as used herein refers to a vehicle anywhere near to the referred vehicle within a communication range of the referred vehicle, wherein the communication range is defined as the maximum distance where communication can exist between two antennas, one of which is user's vehicle antenna in a wireless network. It may or may not be an autonomous vehicle. It may or may not have been enabled for V2V communication. In some embodiments, a neighboring vehicle may more specifically refer to a vehicle that is immediately in the next lane or behind the vehicle.

The term “test schedule” as used herein refers to a list of activities or tasks of the test process, defining the start and finish time or location, and interdependencies of such tasks.

The term “test pattern” as used herein refers to a set of rules applied to carry out a list of tasks or activities of the test process.

Business problem: Many drivers find it difficult and troublesome when parking their vehicle in a garage or a parking space. The problem is more difficult when a driver attaches, for example, a trailer, to the vehicle, as the length of the vehicle changes. There is difficulty in backing up the vehicle because the vehicle needs to be driven differently. Thus, there is a need for a method of assisting a driver when an additional item is attached to the vehicle. Further, to ensure safe maneuver of the vehicle and the item, there is a need to ensure that the sensors and devices of the vehicle and the item are in working condition. Further, when verifying if all the devices, such as brake lights, sensors, cameras or turn signals of the attached item are in proper working condition, the existing systems require two or more persons to test the device operations, one to actuate the device and one to verify the operation.

Technical problem: In general, parking a vehicle in a garage or reversing a vehicle is difficult and troublesome for some drivers. Further, when an attachment is attached to the vehicle such as a trailer, it becomes more difficult to reverse the vehicle trailer combination or maneuver the trailer. There may be available devices external to the vehicle, such as sensors, but they do not assist in the parking of the item attached to the vehicle. There is a need for systems and methods to determine the devices external to the vehicle and the devices of item(s) and utilize the devices. Further, there is no efficient way to verify if all the devices, such as brake lights, sensors, cameras or turn signals are in proper working condition, when an item (e.g., a trailer) is attached to the main vehicle.

Business solution: A driver of a vehicle that has an item attached to the vehicle, needs assistance to park the vehicle attachment combination or to maneuver the attached item. There may be external devices such as sensors, lights, etc. available that may be able to assist the driver to maneuver the attached item as needed. The system utilizes the available external devices to carry out a function of the attached item in an inexpensive, simple and reliable way. Further, by using such external devices, the system can verify the functioning of the devices of the vehicle and the devices of the item in an efficient manner.

Technical solution: In an aspect, there may be external devices available when parking a vehicle with an attached item into a parking lot. The system uses the external devices to carry out a required function of the attached item. There may further be devices which are part of the vehicle and devices which are part of the attached item, that may be used to assist the driver in carrying out a function of the attached item. Further, the system utilizes one or more resources (e.g., mobile phone or a key FOB) for verification of the functionality of the devices of the vehicle and item.

Technical Result: The system of assisting a driver when an additional item is attached to the vehicle is provided. Accordingly, the system utilizes devices of the vehicle, devices of the item, and devices external to the vehicle item combination to carry out a function of the item attached to the vehicle. The system further tests the devices of the vehicle and the item, verifying the functionality of the devices individually and through a test pattern.

How a Technical Solution is a Technological Advancement: The system is designed to address the challenge faced by drivers when an item is attached to the vehicle. The system leverages advanced technologies, including machine learning, bidirectional communication, identification and utilization of devices of the vehicle, devices of the item, and devices external to the vehicle item combination, to assist the driver to carry out a function of the attached item. The system is further designed to test the devices of the vehicle and the item individually through a test pattern.

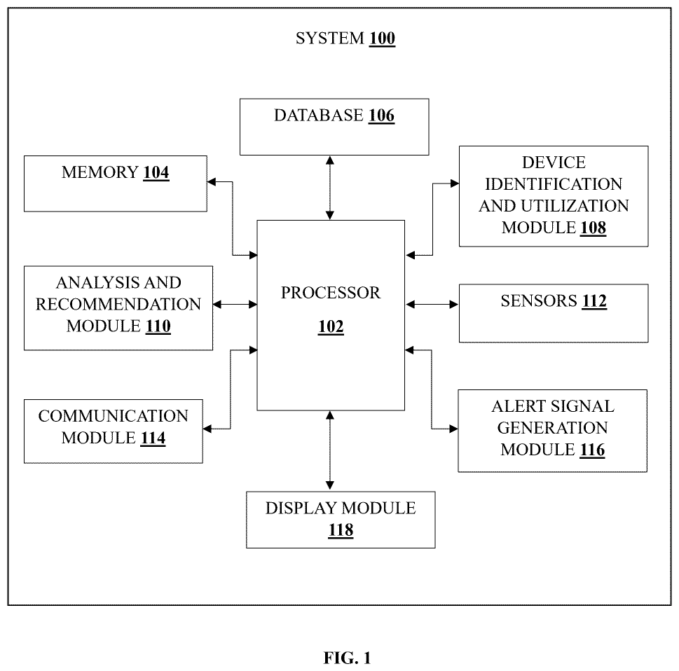

Technical Details Specific to the Technical Solution: FIG. 1 illustrates a block diagram of a system for assisting a driver when an additional item is attached to the vehicle.

System 100 comprises processor 102, memory 104, database 106, device identification and utilization module 108, analysis and recommendation module 110, sensors 112, communication module 114, alert signal generation module 116, and display module 118.

Referring to FIG. 1, processor 102 may be a high-performance, multi-core CPU or system-on-chip (SoC) solution to process vast amounts of data. In some embodiments, processor 102 processes data from database 106, sensor 112, and other inputs to make real-time decisions related to utilizing the external devices to assist the driver of the vehicle. Processor 102 further processes data to make real-time decisions regarding the testing of the devices of the vehicle and testing the devices of the attached item. Processor 102 may comprise Graphics Processing Units (GPUs). GPUs are utilized for their ability to accelerate tasks like data processing. The processor may depend on factors such as processing requirements and power consumption. Processors, also known as central processing units (CPUs), are the heart and brain of any computer or electronic device capable of executing instructions. Processor or processors'function is to process data and perform calculations, etc. At the core of their operation lies data processing, where they handle arithmetic and logical operations on data stored in memory. CPUs execute instructions, which are sets of specific operations encoded in machine language, to perform various tasks. The control unit within, or interacting with, the processor manages and coordinates the execution of instructions, fetching them from memory, decoding them, and directing the appropriate components to execute the instructions. To ensure a controlled and orderly flow of tasks, processors use an internal clock that generates regular electrical pulses, synchronizing their operations through clock cycles. Processors support multitasking environments, rapidly switching between executing different tasks for various applications. Additionally, they may work with the operating system to manage virtual memory, allowing programs to access more memory than is physically available, and to efficiently manage memory usage. Processor or processors may be integrated with security features, including hardware-level encryption, memory protection, and support for secure execution environments, enhancing the system's security against potential threats. The processor may run sophisticated algorithms and artificial intelligence (AI) software to analyze input data, determine conditions associated with the vehicle and the item, interpret the environment, and help in decision making. In an embodiment, the processor may be a neuromorphic processor, inspired by the human brain, which offers a unique approach to handling AI tasks. Processor 102 interacts and exchanges data with one or more of the other components or modules of the system, and computes and processes the information from the devices external to the vehicle, devices of the vehicle, and devices of the attached item, and controls and coordinates memory 104, database 106, device identification and utilization module 108, analysis and recommendation module 110, sensors 112, communication module 114, alert signal generation module 116, and display module 118. The processor may determine the devices to be used in real time to carry out a function of the item.

Referring to FIG. 1, memory 104 may be a non-volatile memory (NVM) which is utilized in reliable operations of the system, ensuring that data is preserved even during power interruptions or failures. Various NVM technologies are utilized, such as flash memory for storing the operating system and software, EEPROM for retaining configuration data, calibration values, and sensor settings, Ferroelectric RAM (FRAM) for critical real-time information, and emerging technologies like ReRAM for potential performance enhancements due to its high-speed operation and low power consumption. In an embodiment, the memory may be a cloud-based memory. In another embodiment, the memory may be a local memory. In another embodiment, the memory may be a combination of local and cloud-based memory. Local memory refers to the traditional memory components present in a physical device, such as a computer's RAM, hard disk drives (HDDs), or solid-state drives (SSDs). It provides fast access to data, making it suitable for immediate processing tasks and offline use. On the other hand, cloud-based memory relies on remote servers and services provided by third-party cloud providers to store and manage data over the internet. Systems can access their data from anywhere with an internet connection, allowing for seamless collaboration and scalability. Cloud-based memory is often used for storing large amounts of data, enabling data sharing, and providing backup and disaster recovery solutions. The combination of local memory and cloud-based memory allows for flexible and efficient data management tailored to different needs of the system.

Referring to FIG. 1, in some embodiments, database 106 may store data associated with device identification and utilization module 108, analysis and recommendation module 110, sensors 112, alert signal generation module 116, and display module 118. In some embodiments, database 106 may be locally present in system 100 or may be present in a cloud server. Processor 102 may fetch the data from the database to determine the external devices needed to carry out a function of the attached item. Processor 102 may fetch the data from the database for testing the devices of the vehicle and the devices of the attached item.

Referring to FIG. 1, device identification and utilization module 108 identifies devices associated with the item and devices external to the vehicle and item. Vehicle and item may also be referred to as vehicle item combination. The system comprises necessary software and hardware to enable identification and utilization of such identified devices. For example, the vehicle may be a towing vehicle and the devices might be available on the towed vehicle. Such devices could be sensors and lights associated with the towed vehicle. To enable a towing vehicle to detect sensors, and other relevant information from a towed vehicle and its dolly or trailer, a system involving various sensors, communication protocols, and power connections including power management module is established on both the towed vehicle and the towing vehicle. The components of the system on the vehicle comprises communication interface, sensor integration and power management module. The components of the system on the item comprises a communication system, sensor network and power supply recognition from the vehicle.

The one or more devices may provide a notification to the driver concerning vehicle's position relative to a parking spot in the garage and/or data related to a distance value measuring the vehicle position to a wall of the garage. The module may transmit the notification and data to the vehicle system via a wireless communication link. In one example, a garage camera may transmit data comprising distance and/or vehicle position to the vehicle system using the wireless communication link. The one or more devices may provide data comprising an angle of view not available using on-vehicle parking sensors and/or the on-vehicle rear view camera.

The item may establish a sensor network from the sensor array associated with the item comprising battery sensors, brake sensors, light sensors, communication module, etc. Each sensor is equipped with unique identifiers for data retrieval by the vehicle. These sensors may be connected to a microcontroller or central processing unit within the item. The communication system of the item is capable of broadcasting its sensor data to the vehicle. Communication system facilitates communication between the item and the vehicle for various scenarios including identification and utilization of devices available with the vehicle item combination. Communication protocols for real-time communication between the vehicle and the item may be CAN (Controller Area Network), Bluetooth® or Wi-Fi®, RFID (Radio-Frequency Identification). Communication parameters may be operable to ensure secure data exchange. Security measures ensure that only authorized towing vehicles can access this data. A handshake or identification process between the vehicle and the item may be established by the system.

Referring to FIG. 1, analysis and recommendation module 110 may develop strategies by collecting and analyzing diverse sets of data from the vehicle devices, item devices, and devices external to the vehicle and item, for predicting a set of devices that may be utilized to carry out a function of the item. The analysis and recommendation module may calculate parking assist data that includes vehicle trajectories, object detection, a parking target position, and the size of the parking spot. For example, if the parking space is located in the garage, the target distance value may include a current vehicle position relative to a garage wall facing the front of the vehicle. In response to the target distance value containing the current vehicle position relative to the garage wall, the distance threshold value may equal a predefined distance value keeping the vehicle a defined distance from the garage wall. Similarly the system also finds the target distance value from the side walls. The detected object may include parking spot information such as parking lines, structure data (walls, railings, for example), vehicles parked next to the parking spot, and/or an unidentified object (children, toys, bikes, etc., for example). Leveraging machine learning algorithms, Artificial Intelligence (AI) may predict the potential devices that may be needed for a function of the item. By considering factors like terrain, weather, traffic, user behavior, and vehicle behavior, AI can estimate the set of devices needed with a higher degree of accuracy; and the estimation, using predictive analytics, relies on advanced machine learning algorithms to analyze a wealth of vehicle data, vehicle combination data, user data, and various driving conditions.

The process begins with data collection and preprocessing, where historical vehicle data on vehicle combinations, energy consumption, speed, acceleration, stability, maneuverability, and driving behavior is combined with real-time information on weather conditions, traffic, and terrain. Relevant features are extracted from this comprehensive data set for predicting the needed devices.

An appropriate machine learning algorithm is selected that can provide the estimation for the set of devices. Example modules include Regression models, time series analysis, and neural networks. The chosen model is then trained on the preprocessed dataset to understand the relationships between different variables and their impact on the vehicle's safety range. Predictive analytics further integrates real-time data. The model continuously incorporates up-to-date information on weather conditions, traffic patterns, and other relevant factors, ensuring that the predictions are adaptive and responsive to dynamic driving conditions. Predictive analytics can also optimize the route to maximize safety and maneuverability.

The sensor(s) 112 may include a variety of sensors for monitoring the operation and/or environment in which a vehicle may be operating. The sensor(s) may include, but are not limited to, tire pressure sensors, tire blowout sensors, cameras, water sensors, collision sensors, traction control sensors, speed sensors, brake sensors, scales, radio frequency identification receivers, a vehicle computer, etc. The vehicle may be a car, van, etc. The vehicle may include an electronic navigation system including a global positioning system (GPS) receiver. The vehicle may include a variety of sensors for monitoring components of the attached item. The sensors may be connected (e.g., using CAN bus, etc.) to an onboard computer that uses inputs received from the sensors to assist the driver of the vehicle when an item is attached to the vehicle, and the communication module transmits message to the devices external to the vehicle item combination, and devices of the item. The GPS receiver may collect location information as the vehicles travel along a roadway. In an example, a first image may be obtained of the vehicle from the sensor data. For example, an image may be received from a camera included in the sensor(s). A second image of an area around the vehicle and the attached item may be obtained from the sensor(s). For example, an image of the roadway behind the attached item may be obtained from the camera included in the sensor(s). For example, the second image may be analyzed to determine that the item may be reversed into the area. In an example, a measurement may be obtained between the vehicle and the sensor(s) from the sensor data. For example, a distance measurement may be obtained between a tire of the vehicle and a depth sensor included in the sensor(s). The data may be obtained directly from sensor(s), camera and/or from the onboard computer of the vehicle, the devices external to the vehicle, devices of the vehicle and the devices of the item, including sensors. The information received from the sensors as mentioned herein may be the device information that is received by the system. The information may include images, measurements, and other data that may be used to provide assistance to the driver of the vehicle.

Referring to FIG. 1, sensors 112 may comprise various sensors such as a temperature sensor, ultrasonic sensors, LIDAR sensors, radar sensors, camera-based sensors, Infrared (IR) sensors, radio frequency identification (RFID) sensors, etc. Sensors, for example, including cameras, LIDARs, radars, and ultrasonic sensors enable autonomous vehicles to detect and recognize objects, obstacles, and pedestrians on the road to enable navigation of the autonomous vehicles. In some embodiments, communication module 114 facilitates communication between different modules within system 100, communication between the vehicle and other devices, other vehicles, and other infrastructure components. In an embodiment, the sensors 112 may comprise a laser radar, an infrared-ray radar, a millimeter-wave radar, an image identification device, a short-range wireless device, or an optical communication device capable of detecting the location and angle of the vehicle and the attached item. According to an embodiment of the system, one or more sensors comprise a magnetic sensor, a proximity sensor, a load sensor, an electrical sensor, and a vision sensor. In an embodiment, the sensors may comprise a plurality of multi-modal sensory arrays, that may include a plurality of microphones for obtaining audio information, a plurality of video cameras for obtaining video information, and one or more movement-related sensors for obtaining vehicle movement-related information.

In an embodiment, capacitance-based sensors are used. One common implementation of capacitance-based sensors for trailer detection is through the use of electrical connectors. Many trailers have electrical connectors that plug into corresponding receptacles on the vehicle. These connectors are used to transfer electrical signals for lighting and other systems on the trailer. Capacitance sensors can detect the presence of a connected trailer by monitoring changes in capacitance when the electrical connector is plugged in or disconnected. In an embodiment, mmWave radar sensors can be used to detect trailers attached to a vehicle, particularly when the trailer has sufficient reflective surfaces, such as metal parts. Such metal reflective surfaces can be provided on the trailers for detection purposes. This sensor fusion approach allows the system to leverage the strengths of each sensor type and provide comprehensive perception of the detection of the attached trailer as well as further details of the trailer. Sensor fusion is the process of combining data from multiple sensors to improve the accuracy, reliability, and efficiency of the information collected. It involves integrating information from various sources, such as cameras, radar, LIDAR, and other sensors, to obtain a more complete and more accurate picture of the environment. Sensor fusion may be able to reduce errors and uncertainties that can arise from using a single sensor and to obtain a more comprehensive understanding of the surrounding world. By combining data from multiple sensors, vehicle systems can make more informed decisions and respond to changing conditions in real-time. According to an embodiment, an AI-based trailer detection may be used in combination with sensor fusion techniques. Some of the algorithms that are suitable for trailer detection include, but are not limited to: (i) Hough Transform: the Hough Transform, (ii) Convolutional Neural Networks (CNNs): CNNs. The sensors may select a region of a road of travel behind the attached item of the vehicle based on sensor data indicative of the road of travel behind the vehicle based on a speed and the location of the vehicle and based on the speed and location of the nearby vehicles, the processor determines a maneuvering profile having a plurality of phases for the vehicle to maneuver the attached item. The plurality of phases may include more than one maneuver, such as a reverse movement of the vehicle followed by an unloading of contents of the item. In an embodiment, the processor may determine a path for the vehicle and attached item based on contact free zone reversing.

Referring to FIG. 1, communication module 114 is coupled to processor 102. Further it facilitates communication between different modules within the system, communication between the item and the vehicle, communication between the vehicle and the devices external to the vehicle item combination. The communication module 114 may gather information from the devices external to the vehicle and transmit it to the processor, and the processor 102 is configured to provide assistance to the driver based on the received information.

The communication module 114 enables in-vehicle communication, communication with other vehicles, infrastructure communication, grid communication, etc., using Vehicle to network (V2N), Vehicle to infrastructure (V2I), Vehicle to vehicle (V2V), Vehicle to cloud (V2C), Vehicle to pedestrian (V2P), Vehicle to device (V2D), Vehicle to grid (V2G), and Vehicle to everything (V2X) communication systems. Thus, communications with the vehicle systems may be through one or more interfaces, including but not limited to Universal Serial Bus (USB), Media Oriented System Transport (MOST) bus, Control Area Network (CAN) bus, Ethernet, Universal Asynchronous Receiver-Transmitter (UART) or Serial Peripheral Interface (SPI). The vehicle uses, for example, a message protocol, a message that goes to the other vehicles via a broadcast. The communication module 114 may comprise hardware such as an audio or video recorder and software such as methods, programs and algorithms that would enable recording the data from external devices. In an embodiment, the communication module 114 may provide content, information, data, and/or media associated with the vehicle and the attached item to the vehicle and one or more devices such as mobile phones, a device that is located, or associated with the vehicle, a wearable device, wearable computers, and the like.

The information from the external devices, devices of the vehicle, and devices of the attached item may further be transmitted or received over a communications network using a transmission medium via the communication module utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet mobile telephone networks (e.g., cellular networks), Plain Old Telephone (POTS) networks), and wireless data networks (e.g., Institute of Electrical and. Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, the communication module may include one or more physical jacks (e.g., Ethernet, coaxial, or phone jacks) or one or more antennas to connect to the communications network. In an example, the communication module may include a plurality of antennas to wirelessly communicate with, using at least one of single-input multiple-output (SIMO), multiple-input multiple-output (MIMO), or multiple-input single-output (MISO) techniques. The term “transmission medium” shall be taken to include any intangible medium that is capable of storing, encoding or carrying instructions for execution by the vehicle, and includes digital or analog communications signals or other intangible medium to facilitate communication of such software. The communication module may comprise a hardware component comprising a microcontroller, a transceiver, a power management integrated circuit, an Internet of Things device capable of transmitting one of an analog and a digital signal over one of a telephone, a communication either wired or wirelessly.

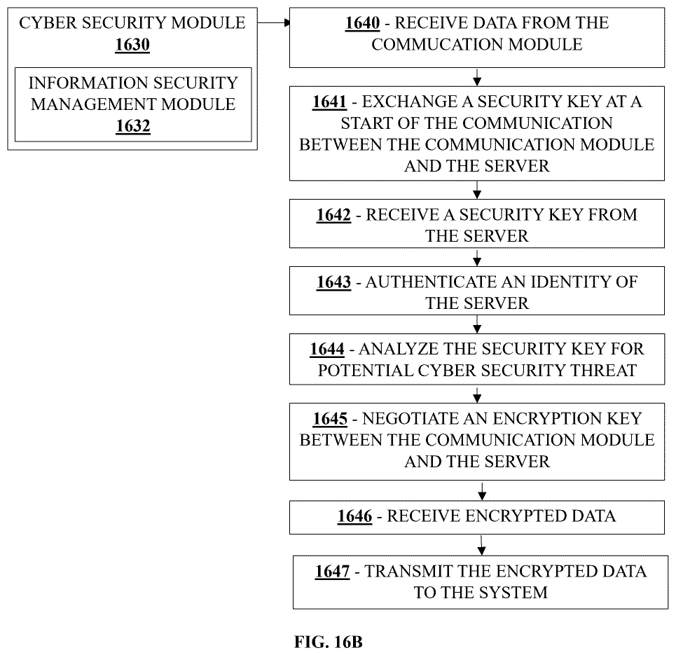

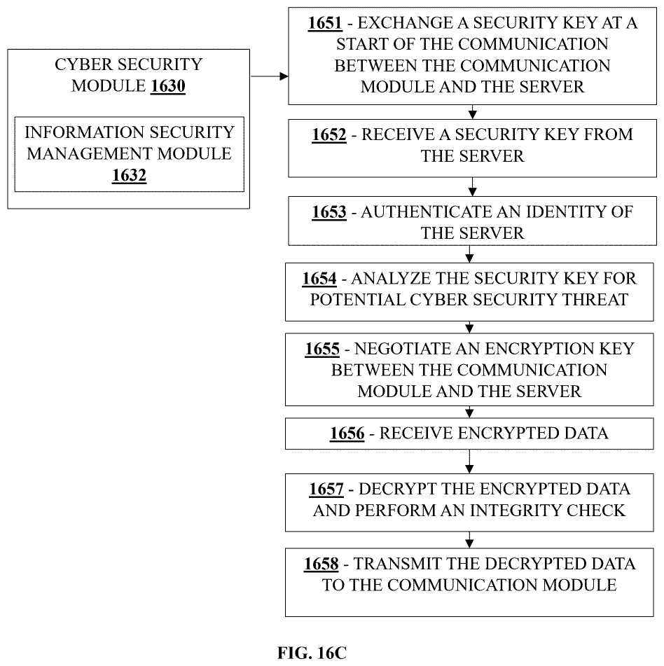

In an embodiment, communication module 114 may comprise a cyber security module 1630 (shown in FIG. 16A). In some embodiments, communication module 114 may communicate with cyber security module 1630 to perform secure communication with nearby devices and external networks. In one aspect, a secure communication management (SCMT) computer device is provided for providing secure communication. The SCMT computer device comprises a processor in communication with memory. The processor is programmed to receive, from a first device, a first data message. The first data message is in a standardized data format. The processor is also programmed to analyze the first data message for potential cyber security threats. If the determination is that the first data message does not contain a cyber security threat, the processor is further programmed to convert the first data message into a first data format associated with the vehicle environment, and transmit the converted first data message to the vehicle system using a first communication protocol associated with the vehicle system. According to an embodiment, secure authentication for data transmissions comprises, provisioning a hardware-based security engine (HSE) located in communication systems, said HSE having been manufactured in a secure environment and certified in said secure environment as part of an approved network, performing asynchronous authentication, validation and encryption of data using said HSE, storing user permissions data and connection status data in an access control list used to define allowable data communications paths of said approved network, enabling communications of the communications system with other computing system subjects to said access control list, performing asynchronous validation and encryption of data using a hardware-based security engine including identifying a user device (UD) that incorporates credentials embodied in hardware using a hardware-based module provisioned with one or more security aspects for securing the system, wherein security aspects comprising said hardware-based module communicating with a user of said user device and said HSE.

Referring to FIG. 1, alert signal generation module 116, is an aspect of communication that serves to draw immediate attention to specific events, conditions, or situations that require prompt action or awareness. For example, an alert signal to alert the user when the vehicle item combination is out of the contact free zone or when the trailing distance is not large enough given the vehicle combination details. These alert signals are designed to be noticeable, distinctive, and easily recognizable, ensuring they effectively convey the urgency of the situation to the intended recipients. The generation of alert signals takes various forms, depending on the context and the target audience.

In an embodiment, alert signals may be audible alarms. They can range from simple beeps or chimes to attention-grabbing sirens. In an embodiment, it may be a visual alert. Bright and conspicuous visual signals, such as flashing screen, flashing LED displays, flashing text, are employed to draw attention. In addition to auditory and visual alert, haptic feedback may also be present. Haptic feedback provides alert signals through tactile sensations, such as vibrations or pulses. This form of alert may be used in smartphones and wearable devices to notify users of the messages without relying solely on sound or visuals. In an embodiment, an alert signal may be a text message, an email, app notifications utilized to generate alert signals on electronic devices. In various contexts, alert signals are used to notify drivers of potential issues when carrying out a function of the item.

Referring to FIG. 1, display module 118 may be connected to the alert signal generation module through the vehicle's onboard computer or electronic control unit (ECU) according to an embodiment. The alert signal generation module may further control information displayed on an infotainment system of the vehicle or instrument cluster through the display module. The display module may also include algorithms for generating further content and controlling how it is displayed. The system constantly monitors various parameters related to the vehicle combination safety, including sensor data, traffic data, maneuverability of the vehicle combination, stability of the vehicle combination, vehicle reaction time, driver reaction time, weather data, and driving patterns. Modern vehicles use Controller Area Network (CAN) or other communication protocols to transmit data between different electronic components and modules, and the display module.

The display system is operable to display a 360 degree bird's eye view of the surroundings of the vehicle and the item connected to it. The system requires minimal effort from the user/driver of the towing vehicle to calibrate the system for the hitched trailer, during which a satellite trailer camera is calibrated, and the trailer dimensions are detected or estimated. The system creates or generates a three dimensional (3D) model for the hitched trailer and, using the 3D model, provides the two dimensional surround view display or the three dimensional surround view display showing the vehicle and trailer. The system may, when the vehicle is shifted into a reverse gear, automatically update the display system to show a display of images derived from image data captured by the rearward viewing trailer camera and surrounding cameras.

It would be appreciated by a person ordinarily skilled in the art that system 100 is not restricted to only the components shown in FIG. 1 and may include various other components.

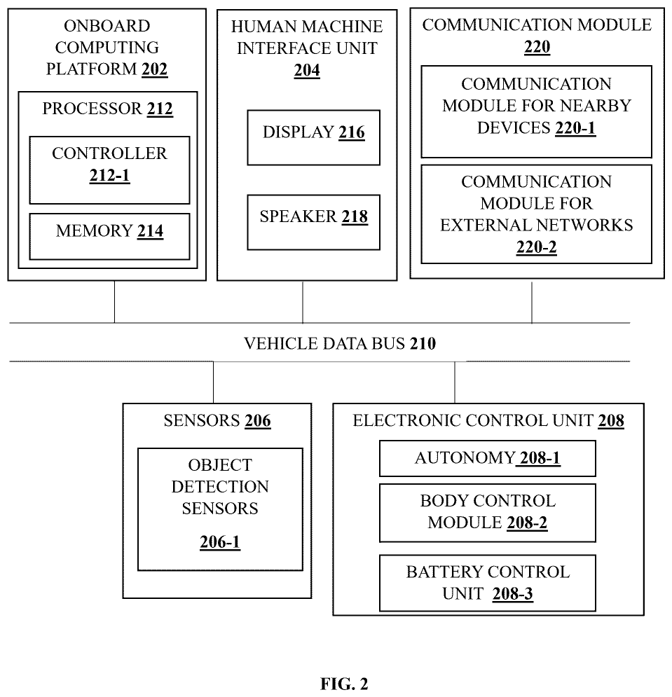

FIG. 2 illustrates a block diagram of various electronic components of the vehicle according to an embodiment.

Referring to FIG. 2, the vehicle comprising various electronic components, such as, onboard computing platform 202, human-machine interface (HMI) unit 204, communication module 220, sensors 206, electronic control units (ECUs) 208, and vehicle data bus 210 are shown. Onboard computing platform 202 comprises processor 212 (also referred to as a microcontroller unit or a controller) and memory 214. In the illustrated example, processor 212 of the onboard computing platform is structured to comprise a controller 212-1. In other examples, controller 212-1 is incorporated into another ECU with its own processor and memory. The processor may be any suitable processing device or set of processing devices such as, but not limited to, a microprocessor, a microcontroller-based platform, an integrated circuit, one or more field programmable gate arrays (FPGAs), and/or one or more application-specific integrated circuits (ASICs). The memory may be volatile memory (e.g., RAM including non-volatile RAM, magnetic RAM, ferroelectric RAM, etc.), non-volatile memory (e.g., disk memory, FLASH memory, EPROMs, EEPROMs, memristor-based non-volatile solid-state memory, etc.), unalterable memory (e.g., EPROMs), read-only memory, and/or high-capacity storage devices (e.g., hard drives, solid state drives), etc. In some examples, memory 214 comprises multiple kinds of memory, particularly volatile memory, and non-volatile memory. Memory 214 is computer-readable media on which one or more sets of instructions, such as the software for operating the methods of the present disclosure, can be embedded. The instructions may embody one or more of the methods or logic as described herein. For example, the instructions reside completely, or at least partially, within any one or more of the memory 214, the computer-readable medium, and/or within processor 212 during execution of the instructions.

HMI unit 204 provides an interface between the vehicle and a user. HMI unit 204 comprises digital and/or analog interfaces (e.g., input devices and output devices) to receive input from, and display information for, the user(s). The input devices comprise, for example, a control knob, an instrument panel, a digital camera for image capture and/or visual command recognition, a touch screen, an audio input device (e.g., cabin microphone), buttons, or a touchpad. The output devices may comprise instrument cluster outputs (e.g., dials, lighting devices), haptic devices, actuators, display 216 (e.g., a heads-up display, a center console display such as a liquid crystal display (LCD), an organic light emitting diode (OLED) display, a flat panel display, a solid state display, etc.), and/or speaker 218. For example, the display, the speaker, and/or other input and output device(s) of the HMI unit 204 are operable to emit an alert, such as an alert to request manual takeover to an operator (e.g., a driver) of the vehicle. Further, the HMI unit of the illustrated example comprises hardware (e.g., a processor or controller, memory, storage, etc.) and software (e.g., an operating system, etc.) for an infotainment system that is presented via display 216.

Sensors 206 are arranged in and/or around the vehicle to monitor the interior regions of the vehicle and/or an environment in which the vehicle is driving. One or more of the sensors may be mounted to measure various parameters around an exterior of the vehicle. Additionally, or alternatively, one or more of sensors may be mounted inside a cabin of the vehicle or in a body of the vehicle (e.g., an engine compartment, wheel wells, etc.) to measure properties of the vehicle and/or interior sensing of the vehicle. For example, sensors 206 comprise accelerometers, odometers, tachometers, pitch and yaw sensors, wheel speed sensors, microphones, tire pressure sensors, biometric sensors, ultrasonic sensors, infrared sensors, Light Detection and Ranging (LIDAR/lidar), Radio Detection and Ranging System (radar), Global Positioning System (GPS), millimeter wave (mmWave) sensors, cameras and/or sensors of any other suitable type. According to an embodiment of the system, the one or more sensors associated with the vehicle comprises camera-based sensors or a camera coupled with a computer vision system.

Referring to FIG. 2, ECUs 208 monitor and control the subsystems of the vehicle. For example, ECUs 208 are discrete sets of electronics that comprise their own circuit(s) (e.g., integrated circuits, microprocessors, memory, storage, etc.) and firmware, sensors, actuators, and/or mounting hardware. ECUs 208 communicate and exchange information via vehicle data bus 210. Additionally, the ECUs may communicate properties (e.g., status of the ECUs, sensor readings, control state, errors, and diagnostic codes, etc.) and receive requests from each other. For example, the vehicle may have many ECUs that are positioned in various locations around the vehicle and are communicatively coupled by the vehicle data bus.

In the illustrated example, ECUs 208 comprise autonomy unit 208-1, body control module 208-2, and battery control unit 208-3. For example, autonomy unit 208-1 is operable to perform autonomous and/or semi-autonomous driving maneuvers (e.g., defensive driving maneuvers) of the vehicle based upon, at least in part, instructions received from controller 212-1 and/or data collected by sensors 206 (e.g., object detection sensors 206-1). Further, body control module 208-2 controls one or more subsystems throughout the vehicle, such as power windows, power locks, an immobilizer system, power mirrors, etc. For example, body control module 208-2 comprises circuits that drive one or more relays (e.g., to control wiper fluid, etc.), brushed direct current (DC) motors (e.g., to control power seats, power locks, power windows, wipers, etc.), stepper motors, LEDs, safety systems (e.g., seatbelt pretensioner, air bags, etc.), etc. For example, a battery control unit 208-3 unit is operable to control the bi-directional on-board charger for charging and discharging the vehicle battery based on signals from the processor.

Referring to FIG. 2, vehicle data bus 210 communicatively couples communication module 220, onboard computing platform 202, HMI unit 204, sensors 206, and ECUs 208. In some examples, vehicle data bus 210 comprises one or more data buses. Vehicle data bus 210 may be implemented in accordance with a controller area network (CAN) bus protocol as defined by International Standards Organization (ISO) 11898-1, a Media Oriented Systems Transport (MOST) bus protocol, a CAN flexible data (CAN-FD) bus protocol (ISO 11898-7) and/a K-line bus protocol (ISO 9141 and ISO 14230-1), and/or an Ethernet™ bus protocol IEEE 802.3 (2002 onwards), etc.

In some embodiments, the vehicle comprises a battery module. The battery module may comprise a battery control unit 208-3 operatively coupled to a vehicle battery and an on-board charger. The battery control unit 208-3 may be operable to control the operation of the on-board charger for charging and discharging the vehicle battery.

Referring to FIG. 2, communication module 220 may comprise a near field communication module or a communication module for nearby devices 220-1 and far field communication module or communication module for external networks 220-2. Communication module for nearby devices 220-1 is operable to communicate with other nearby communication devices. In an example, communication module 220 comprises a dedicated short-range communication (DSRC) module. A DSRC module comprises antenna(s), radio(s) and software to communicate with nearby vehicle(s) via vehicle-to-vehicle (V2V) communication, infrastructure-based module(s) via vehicle-to-infrastructure (V2I) communication, and/or, more generally, nearby communication device(s) (e.g., a mobile device-based module) via vehicle-to-everything (V2X) communication. V2V communication allows vehicles to share information such as speed, position, direction, and other relevant data, enabling them to cooperate and coordinate their actions to improve safety, efficiency, and mobility on the road. V2V communications may rely on dedicated short-range communication (DSRC) and other wireless protocols that enable fast and reliable data transmission between vehicles. V2V communication, which is a form of wireless communication between vehicles, allows vehicles to exchange information and coordinate with other vehicles on the road.

V2V communication is typically based on wireless communication protocols such as Dedicated Short-Range Communications (DSRC) or Cellular Vehicle-to-Everything (C-V2X) technology. With V2V communication, vehicles can receive information about potential hazards, such as accidents or road closures, and adjust their behavior accordingly. V2V communication can also be used to support advanced driver assistance systems (ADAS) and automated driving technologies, such as platooning, where a group of vehicles travel closely together using V2V communication to coordinate their movements.

DSRC systems may be installed on vehicles and along roadsides on infrastructure. DSRC systems incorporating infrastructure information are known as “roadside” systems. DSRC may be combined with other technologies, such as Global Position System (GPS), Visual Light Communications (VLC), Cellular Communications, and short range radar, facilitating the vehicles communicating their position, speed, heading, relative position to other objects and to exchange information with other vehicles or external computer systems. DSRC systems can be integrated with other systems such as mobile phones.

Currently, the DSRC network is identified under the DSRC abbreviation or name. However, other names are sometimes used, usually related to a Connected Vehicle program or the like. Most of these systems are either pure DSRC or a variation of the IEEE 802.11 wireless standard. However, besides the pure DSRC system it is also meant to cover dedicated wireless communication systems between cars and roadside infrastructure systems, which are integrated with GPS and are based on an IEEE 802.11 protocol for wireless local area networks (such as 802.11p, etc.).

Additionally, or alternatively, communication module for external networks 220-2 comprises a cellular vehicle-to-everything (C-V2X) module. A C-V2X module comprises hardware and software to communicate with other vehicle(s) via V2V communication, infrastructure-based module(s) via V2I communication, and/or, more generally, nearby communication devices (e.g., mobile device-based modules) via V2X communication. For example, a C-V2X module is operable to communicate with nearby devices (e.g., vehicles, roadside units, mobile devices of users, etc.) directly and/or via cellular networks. Currently, standards related to C-V2X communication are being developed by the 3^{rd} Generation Partnership Project. Further, communication module 220-2 is operable to communicate with external networks. For example, communication module 220-2 comprises hardware (e.g., processors, memory, storage, antenna, etc.) and software to control wired or wireless network interfaces. In the illustrated example, the communication module 220-2 comprises one or more communication controllers for cellular networks (e.g., Global System for Mobile Communications (GSM), Universal Mobile Telecommunications System (UMTS), Long Term Evolution (LTE), Code Division Multiple Access (CDMA)), fifth generation 5G networks, Near Field Communication (NFC) and/or other standards-based networks (e.g., WiMAX (IEEE 802.16m), local area wireless network (including IEEE 802.11 a/b/g/n/ac or others), Wireless Gigabit (IEEE 802.11ad), etc.). In some examples, the communication module for external networks 220-2 comprises a wired or wireless interface (e.g., an auxiliary port, a Universal Serial Bus (USB) port, a Bluetooth® wireless node, etc.) to communicatively couple with a mobile device (e.g., a smart phone, a wearable, a smart watch, a tablet, etc.). In such examples, the vehicle may communicate with the external network via the coupled mobile device. The external network(s) may be a public network, such as the Internet, a private network, such as an intranet, or combinations thereof, and may utilize a variety of networking protocols now available or later developed including, but not limited to, TCP/IP-based networking protocols.

The communication module comprises a hardware component comprising a vehicle gateway system comprising a microcontroller, a transceiver, a power management integrated circuit, an Internet of Things device capable of transmitting one of an analog and a digital signal over one of a telephone, a communication, either wired or wirelessly.

Autonomy unit 208-1 of the illustrated example is operable to perform autonomous and/or semi-autonomous driving maneuvers, such as defensive driving maneuvers, for the vehicle. For example, autonomy unit 208-1 performs the autonomous and/or semi-autonomous driving maneuvers based on data collected by sensors 206. In some examples, autonomy unit 208-1 is operable to operate a fully autonomous system, a park-assist system, an advanced driver-assistance system (ADAS), and/or other autonomous system(s) for the vehicle.

An ADAS is configured to assist a driver in safely operating the vehicle. For example, the ADAS is configured to perform adaptive cruise control, collision avoidance, lane-assist (e.g., lane centering), blind-spot detection, rear-collision warning(s), lane departure warnings and/or any other function(s) that assist the driver in operating the vehicle. To perform the driver-assistance features, the ADAS monitors objects (e.g., vehicles, pedestrians, traffic signals, etc.) and develops situational awareness around the vehicle. For example, the ADAS utilizes data collected by the sensors 206, the communication module 220-1 (e.g., from other vehicles, from roadside units, etc.), the communication module 220-2 from a remote server, and/or other sources to monitor the nearby objects and develop situational awareness.

Further, in the illustrated example, controller (or control module) 212-1 is operable to monitor an ambient environment of the vehicle. For example, the controller may detect overheating of the vehicle battery, and take corrective action, such as stopping the battery charging or discharging, in case of overheating, for a certain time period. For example, to enable autonomy unit 208-1 to perform autonomous and/or semi-autonomous driving maneuvers, the controller collects data that is collected by sensors 206 of the vehicle. In some examples, the controller collects location-based data via communication module 220-1 and/or another module (e.g., a GPS receiver) to facilitate the autonomy unit in performing autonomous and/or semi-autonomous driving maneuvers. Additionally, the controller collects data from (i) adjacent vehicle(s) via communication module 220-1 and V2V communication and/or (ii) roadside unit(s) via communication module 220-1 and V2I communication to further facilitate autonomy unit 208-1 in performing autonomous and/or semi-autonomous driving maneuvers.

In operation, according to an embodiment, the communication module 220-1 performs V2V communication with an adjacent vehicle. For example, the communication module 220-1 collects data from the adjacent vehicle that identifies (i) whether the adjacent vehicle includes an autonomous and/or semi-autonomous system (e.g., ADAS), (ii) whether the autonomous and/or semi-autonomous system is active, (iii) whether a manual takeover request of the autonomous and/or semi-autonomous system has been issued, (iv) lane-detection information of the adjacent vehicle, (v) a speed and/or acceleration of the adjacent vehicle, (vi) a (relative) position of the adjacent vehicle, (vii) a direction-of-travel of the adjacent vehicle, (viii) a steering angle rate-of-change of the adjacent vehicle, (ix) dimensions of the adjacent vehicle, (x) whether the adjacent vehicle is utilizing stability control system(s) (e.g., anti-lock braking, traction control, electronic stability control, etc.), and/or any other information that facilitates the controller 212-1 in monitoring the adjacent vehicle.

Based at least partially on the data that the communication module 220-1 collects from the adjacent vehicle via V2V communication, the controller 212-1 can determine a collision probability for the adjacent vehicle. For example, the controller 212-1 determines a collision probability for the adjacent vehicle in response to identifying a manual takeover request within the data collected by the communication module 220-1 for the adjacent vehicle. Additionally, or alternatively, the controller 212-1 determines a collision probability for the adjacent vehicle in response to identifying a discrepancy between (i) lane-marker locations determined by the controller 212-1 of the vehicle based on the sensors 206 and (ii) lane-marker location determined by the adjacent vehicle. Further, in some examples, the controller 212-1 determines the collision probability for the adjacent vehicle based on data collected from other sources, such as the sensors 206, e.g., range detector sensors and/or other sensor(s) of the vehicle, roadside unit(s) in communication with the communication module 220-1 via V2I communication, and/or remote server(s) in communication with the communication module 220-1. For example, the controller 212-1 determines the collision probability for the adjacent vehicle upon determining, based on data collected by the sensors of the vehicle and the adjacent vehicle, that the adjacent vehicle has not detected a nearby object.

In some examples, the controller 212-1 determines the collision probability based on a takeover time for the adjacent vehicle and/or a time-to-collision of the adjacent vehicle. For example, the takeover time corresponds with a duration of time between (1) the adjacent vehicle emitting a request for a manual takeover to be performed and (2) an operator of the adjacent vehicle manually taking over control of the adjacent vehicle. The controller 212-1 is configured to determine the takeover time of the adjacent vehicle based on measured characteristics of the adjacent vehicle (e.g., velocity, acceleration, dimensions, etc.), the operator of the adjacent vehicle (e.g., a measured reaction time, etc.), and/or an environment of the adjacent vehicle (e.g., road conditions, weather conditions, etc.). Further, the time-to-collision corresponds with the time it would take for the adjacent vehicle to collide with another vehicle (e.g., a third vehicle) and/or object (e.g., a guardrail, a highway lane divider, etc.) if the current conditions were maintained.

Additionally, or alternatively, the controller 212-1 is configured to determine the time-to-collision of the adjacent vehicle based on a velocity, an acceleration, a direction-of-travel, a distance to the object, a required steering angle to avoid the object, a steering angle rate-of-change, and/or other measured characteristics of the adjacent vehicle that the communication module 220-1 collects from the adjacent vehicle via V2V communication. Further, the controller 212-1 is configured to determine a collision probability for the vehicle based on the collision probability of the adjacent vehicle.

Upon determining the collision probability of the adjacent vehicle and determining that the collision probability is not as per threshold, the autonomy unit 408-1 autonomously performs (e.g., for the ADAS) a defensive driving maneuver to prevent the vehicle from being involved in a collision caused by the adjacent vehicle. For example, the autonomous defensive driving maneuver includes deceleration, emergency braking, changing of lanes, changing of position within a current lane of travel, etc. In some examples, the autonomy unit 208-1 is configured to initiate the defensive driving maneuver before the takeover time of the adjacent vehicle has been completed. That is, the controller 212-1 is configured to cause the autonomy unit 208-1 to perform the defensive driving maneuver before the operator of the adjacent vehicle manually takes over control of the adjacent vehicle. Further, in some examples, the controller 212-1 emits an audio, visual, haptic, and/or other alert (e.g., via an HMI unit 204) for the operator of the vehicle to request manual takeover in response to determining that the collision probability is above threshold. By emitting such an alert, the controller 212-1 enables the operator of the vehicle to safely take control of the vehicle before the adjacent vehicle is potentially involved in a collision. Additionally, or alternatively, the controller 212-1 is configured to perform other defensive measures (e.g., prefilling brake fluid lines) in response to determining that the collision probability is above threshold.

In an embodiment, a connection is established between a vehicle and a nearby vehicle, which is a surrounding car. A nearby vehicle is detected by the vehicle control system. The nearby vehicle is detected by exchanging handshaking signals. The handshaking is the automated process for negotiation of setting up a communication channel between entities. The processor sends a start signal through the communication channel in order to detect a nearby vehicle. If there is a nearby vehicle, the processor may receive an acknowledgement signal from the nearby vehicle. Upon receiving the acknowledgement signal, the processor establishes a secure connection with the nearby vehicle. The processor may receive a signal at the communication module from the nearby vehicle. The processor may further automatically determine the origin of the signal. The processor communicatively connects the communication module to the nearby vehicle. Then the processor is configured to send and/or receive a message to and/or from the nearby vehicle. The signals received by the communication module may be analyzed to identify the origin of the signal to determine a location of the nearby vehicle.

In an embodiment, the system is enabled for bidirectional communication. The system sends a signal and then receives a signal/communication. In an embodiment, the communication could be a permission for access to control the other vehicle. In another embodiment, the communication could be an incremental control communication, for example, an initial control of the speed up to 10 miles per hour, then further additional 10 miles per hour, and so on.

As a first step of the method according to the disclosure, a data link between the vehicle and nearby vehicle or any other external device is set up in order to permit data to be exchanged between the vehicle and the nearby vehicle or any other external device in the form of a bidirectional communication. This can take place, for example, via a radio link or a data cable. It is therefore possible for the nearby vehicle or any other external device to receive data from the vehicle or for the vehicle to request data from the nearby vehicle or any other external device.

In an embodiment, bidirectional communication comprises the means for data acquisition and is designed to exchange data bidirectionally with one another. In addition, at least the vehicle comprises the logical means for gathering the data and arranging it to a certain protocol based on the receiving entity's protocol.

Initially, a data link for bidirectional communication is set up. The vehicle and the nearby vehicle or any other external device can communicate with one another via this data link and therefore request or exchange data, wherein the data link can be implemented, for example, as a cable link or radio link.

Bidirectional communication has various advantages as described herein. In various embodiments, data is communicated and transferred at a suitable interval, including, for example, 200 millisecond (ms) intervals, 100 ms intervals, 50 ms intervals, 20 ms intervals, 10 ms intervals, or even more frequent and/or in real-time or near real-time, in order to allow a vehicle to respond to, or otherwise react to, data. Bidirectional Infrared communication may be used to facilitate the data exchange.

The apparatus for the vehicle according to the embodiment that performs bidirectional communication may be by means of a personal area network (PAN) modem. Therefore, a user can have access to an external device using the vehicle information terminal, and can then store, move, and delete the user's desired data.

The communication module enables in-vehicle communication, communication with other vehicles, infrastructure communication, grid communication, etc., using Vehicle to network (V2N), Vehicle to infrastructure (V2I), Vehicle to vehicle (V2V), Vehicle to cloud (V2C), Vehicle to pedestrian (V2P), Vehicle to device (V2D), Vehicle to grid (V2G), and Vehicle to everything (V2X) communication systems. The vehicle uses, for example, a message protocol, a message that goes to the other vehicles via a broadcast.

According to an embodiment, the communication module 220 supports a communication protocol, wherein the communication protocol comprises at least one of a Advanced Message Queuing Protocol (AMQP), Message Queuing Telemetry Transport (MQTT) protocol, Simple (or Streaming) Text Oriented Message Protocol (STOMP), Zigbee protocol, Unified Diagnostic Services (UDS) protocol, Open Diagnostic eXchange format (ODX) protocol, Diagnostics Over Internet Protocol (DoIP), On-Board Diagnostics (OBD) protocol, and a predefined protocol standard. In an embodiment, communication module 220 may comprise a cyber security module 1630 (shown in FIG. 16A). In some embodiments, communication module 220 may communicate with cyber security module 1630 to perform secure communication with nearby devices and external networks.

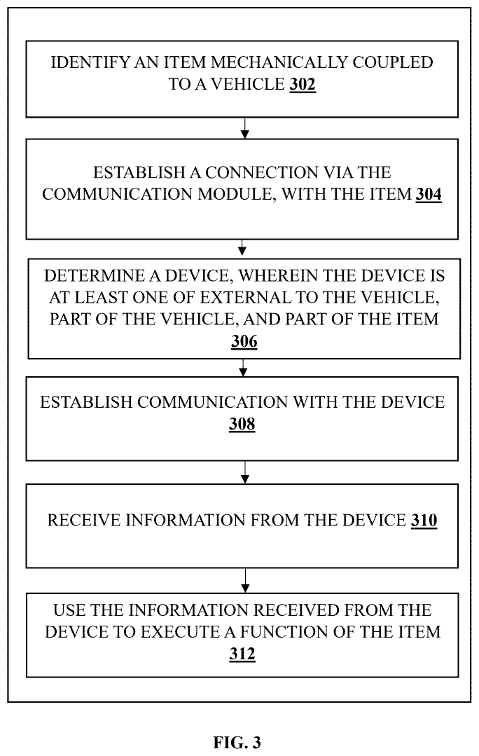

FIG. 3 illustrates a flow chart describing a method for assisting a driver when an additional item is attached to the vehicle.

In some embodiments, the method shown in FIG. 3 may be carried out by a processor using instructions stored in a memory that, when executed, cause the processor to carry out the method. In an embodiment, the method as shown in FIG. 3 may be performed by system 100 as shown in FIG. 1.

Referring to FIG. 3, the method may, at step 302, identify an item mechanically coupled to a vehicle. Method may, at step 304, establish a connection via the communication module, with the item. The method may, at step 306, determine a device, wherein the device is at least one of a device external to the vehicle, a device that is part of the vehicle, and a device this is part of the item. The method may, at step 308, establish communication with the device. The method may, at step 310, receive information from the device. The method may, at step 312, use the information received from the device to execute a function of the item.

In an embodiment, an item may comprise at least one of a trailer, a rack, a recreational vehicle, a stock trailer, a boat trailer, and a cargo carrier. In an embodiment, the device may comprise at least one of a nearby vehicle sensor, a garage sensor, a parking area sensor, an external sensor, an item sensor, an item light, an item signal, an item wiper, an item mirror, a vehicle sensor, a vehicle light, a vehicle signal, a vehicle wiper, a vehicle mirror, and a user device. The device may be configured to provide information regarding at least one of a surrounding vehicle, a surrounding area of the vehicle, and a surrounding area of the item. The information may comprise traffic or obstacle data next to the surrounding vehicle, distance of the vehicle from the surrounding vehicle, distance of the item from the surrounding vehicle, traffic or obstacle data in a predefined proximity of the vehicle, and traffic or obstacle data in a predefined proximity of the item. The predefined proximity of the vehicle and the predefined proximity of the item may be same or different. The proximity may be defined based on the function of the item and the space available to execute a function of the vehicle. In an embodiment, the function of the item may comprise at least one of a maneuver of the item, a loading of the item, an unloading of the item, a reverse movement, a forward movement, a turn movement, and a park movement. Loading the item may refer to the filling of the item or placing contents on the item. Unloading the item may refer to emptying, removing, or discharging of contents of the item.

In some embodiments, the method may further identify a space requirement for the function of the item, determine the device based on the space requirement, and establish communication with the device. The method may further transmit the information from the device to a display system, generate a contact free zone based on the information, display a map on a display system, wherein the contact free zone is highlighted on the map, and execute the function of the item based on the map.

In an embodiment, the method may determine from the information of the device a dimension of the item, determine from the information a dimension of the space requirement, transmit the dimension of the item and the dimension of the space requirement to a display system, and display the dimension of the item and the dimension of the space requirement as an overlay map on the display system, and based on the map, execute the function of the item.

In an embodiment, the device may comprise a plurality of devices and the method may determine from the plurality of devices, at least one device is required in real time to execute the function of the item. In an embodiment, the method may obtain the information from the device by enhancing a feature of the device. In an embodiment, the device may comprise at least one of a radar-based sensor, a LAser Detection And Ranging (LADAR) sensor, a Light Detection and Ranging (LIDAR) sensor, a camera, an infrared camera, a night vision camera, and a thermal camera, a vision-based sensor, a light-based sensor, an infrared sensor, an optical sensor, a temperature sensor, a pressure sensor, a proximity sensor, a GPS sensor, an audio sensor, a stereo vision sensor, a headlight, a taillight, a turn indicator, a brake light, and a back light. In an embodiment, the method may establish communication with a mobile device and acquire the information obtained by the device via an application on the mobile device.

In an embodiment, the communication is via a wireless communication protocol. The communication module may support a communication protocol, wherein the communication protocol comprises at least one of a Hypertext Transfer Protocol (HTTP), Message Queuing Telemetry Transport (MQTT), WebSocket, Constrained Application Protocol (CoAP) and Advanced Message Queuing Protocol (AMQP). The communication module may comprise a V2X telematics communication module and the communication module is enabled for at least one of a vehicle-to-vehicle communication, vehicle-to-infrastructure communication, and vehicle-to-everything communication.

In an embodiment, the system uses external cameras to provide assistance to the driver. For example, if a trailer is attached to the vehicle and the driver wishes to back up, the system can establish communication with external cameras (e.g., cameras in the garage or cameras of parked cars nearby). In an aspect, the user identifies where the attached item needs to go (e.g., backing up a trailer into a garage or a parking spot or reversing), and the system may scan for available cameras and establish communication with only the required cameras. The images from those cameras may be provided to the vehicle's display (e.g., the center console display or the infotainment system). This can allow the driver to utilize the external cameras to maneuver the attached item safely.

In another aspect, the system can use external sensors to avoid contact. In an aspect, the system may scan for available sensors and establish communication so that the system can use the external sensors to avoid contact with obstacles, walls, railings and the like. The system can use cameras and sensors to provide a contact free zone and display that on the screen. In an embodiment, the sensors may produce a different beeping sound based on dynamic information available in the contact free zone. The system may enhance the external cameras (e.g., zoom in or out) as needed. In an aspect, once the system detects an attachment (e.g., a trailer), the system may attempt to access the sensors and cameras of the attachment. If there are no sensors/cameras detected, unavailable or insufficient to carry out the required function (e.g., maneuvering backward), the system may enhance its own cameras (e.g., zoom in or out) as needed. Also, the contact free zone is enhanced to include the attachment if sensors or sensor data are not available from the attachment.

In an embodiment, the system can assist the driver of the vehicle-trailer combination when maneuvering the vehicle trailer combination. For example, the driver can be assisted when reversing and/or during overtaking maneuvers with the vehicle-trailer combination. For this purpose, based on the objects in the surrounding area acquired using the devices of the vehicle and the trailer, and the devices external to the vehicle trailer combination, the vehicle trailer combination can be maneuvered by the controller of the vehicle at least semi-autonomously and/or can be warned with warning signals to avoid contact or collision of the vehicle-trailer combination with objects, obstacles.

The system supports all types of trailers including conventional trailers such as, but not limited to, vehicle haulers, box trailers, utility trailers, loaded and unloaded boat trailers, snow mobiles, and any other custom trailers including fifth wheel or gooseneck type of trailers. The system is operable to perform independent of ambient conditions (such as day, night, sunny, cloudy, rain, snow, etc.) and environmental surfaces (such as concrete, asphalt, gravel, grass, dirt, etc.). The system provides views in such a way that there will be no blind spots shown to the user around the vehicle and/or the trailer.

If a trailer or the vehicle on the trailer has cameras, they can be used to provide information to the driver. Many times, the cameras of the vehicle only provide the view of the vehicle surroundings. But when a trailer is attached, maybe those vehicle cameras are blocked, but if the trailer has cameras, then those cameras, which are devices or resources associated with the trailer, may be used. As a first step the system may determine all of the devices available with the trailer/item and all of the devices external to the vehicle and the item, such as the parking area cameras, garage cameras, and nearby vehicle cameras. The information on the devices and their accessibility gets communicated. In an embodiment, a specification of attachment gets transmitted by the connection between the trailer and the vehicle, and a specification of the external devices that are external to the vehicle and item, gets transmitted by the connection between the external devices and the vehicle. The vehicle receives the communication and then establishes appropriate connections to access the devices of the attachment and the external devices, as needed. In an embodiment, the specification of the attachment comprises Identification Number (VIN), make and model, how many sensors, location of such sensors, and the capabilities of the sensors, how many cameras, location of such cameras, and the capabilities of the cameras. In an embodiment, the specification of the external devices comprises location of sensors, and the capabilities of the sensors, location of cameras, and the capabilities of the cameras. The devices may comprise sensors, cameras, sub-systems, exterior lighting, connectivity equipment, communication infrastructure for V2V communication, V2I communication, etc., relevant data. In an embodiment, the sensors may comprise weather sensors, traffic flow, environmental sensors, location sensors, etc. In an embodiment, the sub-systems comprise navigation system, communication system, external lighting system, etc. In an embodiment, the relevant data comprises sensor data, control data, traffic data, environmental data, etc. During turning maneuvers, the system detects the trailer and estimates dimensions of the trailer (such as but not limited to length, width, height, tongue length, trailer jack position and shape, wheel radius), and may determine other properties of the trailer (such as color, shape of trailer including shape of trailer tongue, trailer jack). The system also determines the physical position of the trailer satellite camera(s) on the trailer (such as extrinsic camera angles and displacement with reference to a datum point of the vehicle).

In an embodiment, the rear trailer camera is disposed at a rear portion of the trailer, such as at the back end of the trailer, with the trailer camera centrally located at the rear portion and having a field of view at least rearward (and downward) at the rear of the trailer. For detecting objects behind and at an angle behind the trailer, the radar sensor is disposed or mounted on the rear area of the trailer, so that a direction of view or a detection region of the radar sensor starting from the rear area of the trailer is directed to the rear or in the rearward direction. From the radar signals, information can be extracted about the object, for example an angle or a direction to the object, a distance to or a separation from the object and a relative movement between the radar sensor or the trailer and the object. The system uses the 3D trailer model in place of the actual trailer position and aligns/stitches the vehicle surround view with trailer surround view or trailer rear satellite camera(s).

The system is operable for receiving data or extracting data from the attached item. The data may include Vehicle identification number (VIN), length of the item, height of the item, and weight of the item, information regarding the various devices of the item, such as sensors, lights, and signals. This information can be gathered wirelessly, wired or from the operator. The system adaptively determines a contact free zone based on the information received from the item that was added. In an aspect, a connector is provided that is capable of two way communication with any item that is being attached. Upon attachment, the system initiates communication via the connector of the item that is being attached. Once the communication is established, the system extracts data from the devices of the item. In one aspect, the communication is wireless using a protocol.

In another aspect, the system is capable of receiving active data from the sensors connected to the item (e.g., trailer having various sensors). The data from these sensors is provided to the vehicle system. Using these sensors, the vehicle can adaptively execute a function of the item. Once the item/trailer is attached to the vehicle and upon establishing a two way communication, the system begins monitoring any and/or all sensors that are available on the trailer system to assist the driver for carrying out a function of the item.

In another example, if the driver/operator places the vehicle in reverse (R) the system, using the sensors of the attached item and the devices external to the vehicle item combination, may estimate a contact free zone for carrying out a function of the item.

In an embodiment, the system includes a coupled vehicle-trailer state estimator that uses multiple vehicle sensors together to predict a state of the equipped vehicle and trailer (e.g., a position, a heading, linear velocity, angular velocity, etc.) for automated trailering features. The system predicts a vehicle-trailer state based on a kinematic model (e.g., a bicycle or car-like robot model). The system uses the vehicle-trailer state to calculate path deviation in the path planner and subsequent corrections to be made by vehicle control algorithms as part of automated trailering features. The system corrects the prediction using measurements from multiple sensors to improve accuracy of the vehicle-trailer state estimate. Advantageously, the system may automatically tune and adapt to vehicles of varying trim levels containing varying subsets of sensors with differing levels of accuracy, precision, and sensitivity. The system may be tuned with a tuning process using measurement noise covariance matrices that are initialized with direct experimental measurements (when possible or practical), sensor characterization properties, and engineering intuition followed by parameter tuning through numerical optimization to capture unmodeled process and measurement characteristics. The system may also address sensor dead zones encountered during a maneuver.

The system may perform the prediction and correction of the vehicle and trailer state using various types of nonlinear filters such as an Extended Kalman Filter, an Unscented Kalman Filter, Particle filters, and/or an Error-State Kalman Filter, etc. The sensors that the system may use to correct the vehicle and trailer state estimation may include some or all of the following: a gyroscope, an accelerometer, a steering angle sensor, a pinion angle sensor, one or more wheel revolutions per minute (RPM) sensors, one or more wheel pulse sensors, a magnetometer and/or compass, a global positioning system (GPS) sensor, and one or more imaging sensors (e.g., one or more cameras on the vehicle and/or trailer).

In an embodiment, the system may further comprise a user terminal or a user device. User terminal is capable of being operated by a user. The user terminal may comprise an augmented reality (AR) device (comprising an AR display or being capable of delivering augmented reality images to a suitable display), at least one image sensor such as a digital camera, a processor device such as a computer system and a communications interface. The user terminal also comprises a computer memory capable of stored acquired images. For example, the user terminal is a smartphone, or an electronic tablet, or a portable computer, or a computer workstation, or a virtual reality headset, or similar. The augmented reality (AR) display may be implemented with a screen displaying an AR interface. In many embodiments, the AR interface may be provided by the terminal, e.g. through a dedicated virtual reality (VR) device in communication with the terminal, or by an AR software application executed by a processor of the terminal.

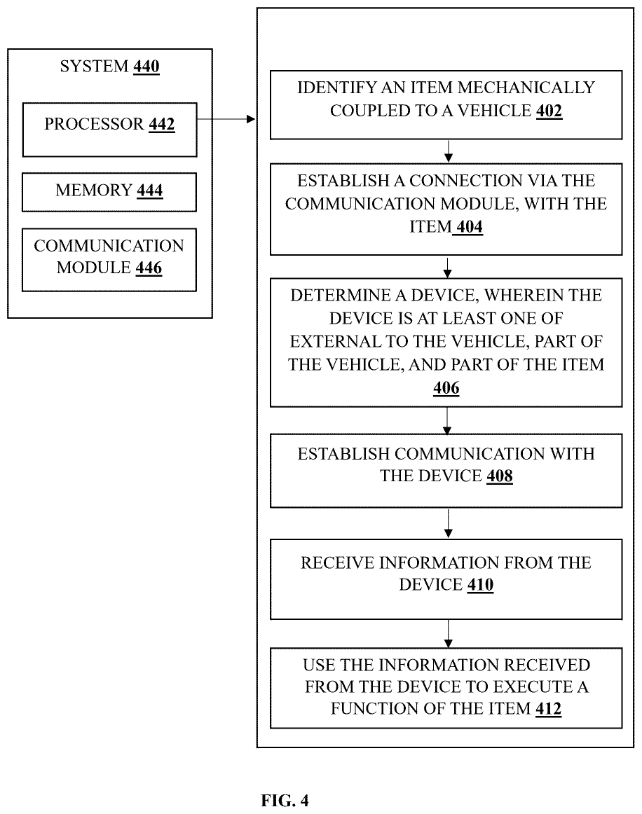

FIG. 4 illustrates a block diagram of the system implementing the method according to an embodiment. According to an embodiment, disclosed is system 440 comprising processor 442, memory 444, and communication module 446, wherein the memory 444 storing processor-executable instructions, which on execution, cause the processor to: identify an item mechanically coupled to a vehicle 402, establish a connection via the communication module, with the item 404, determine a device, wherein the device is at least one of external to the vehicle, part of the vehicle, and part of the item 406, establish communication with the device 408, receive information from the device 410, and use the information received from the device to execute a function of the item 412.

In an embodiment, the system may further identify a space requirement for the function of the item, determine the device based on the space requirement, and establish communication with the device. The system may further transmit the information from the device to a display system, generate a contact free zone based on the information, display a map on a display system, wherein the contact free zone is highlighted on the map, and execute the function of the item based on the map. In an embodiment, the system may further determine from the information of the device a dimension of the item, determine from the information a dimension of the space requirement, transmit the dimension of the item and the dimension of the space requirement to a display system, and display the dimension of the item and the dimension of the space requirement as an overlay map on the display system to execute the function of the item. In an embodiment, the system may determine from the plurality of devices, at least one device required in real time to execute the function of the item. In an embodiment, the system may obtain the information from the device by enhancing a feature of the device. In an embodiment, the system may generate a machine learning model, obtain the information from the device, transmit the information to the machine learning model, wherein the machine learning model is configured to: predict based on the information, an optimized way to execute the function of the item.

During object recognition the processor determines a portion of the image including the images received from the external devices, the devices of the vehicle, and the devices of the attached vehicle, using object recognition techniques, such as convolutional neural networks (CNNs). Once the portion of the image including an obstruction is identified, the processor crops the image, so that a portion of the image, for example, the majority of the image, depicts the obstruction with regard to the maneuver of the attached item. Object recognition via the processor may be performed using machine learning algorithms by performing video analytics of a real-time video through the artificial intelligence model and image processing of an image through the artificial intelligence model.

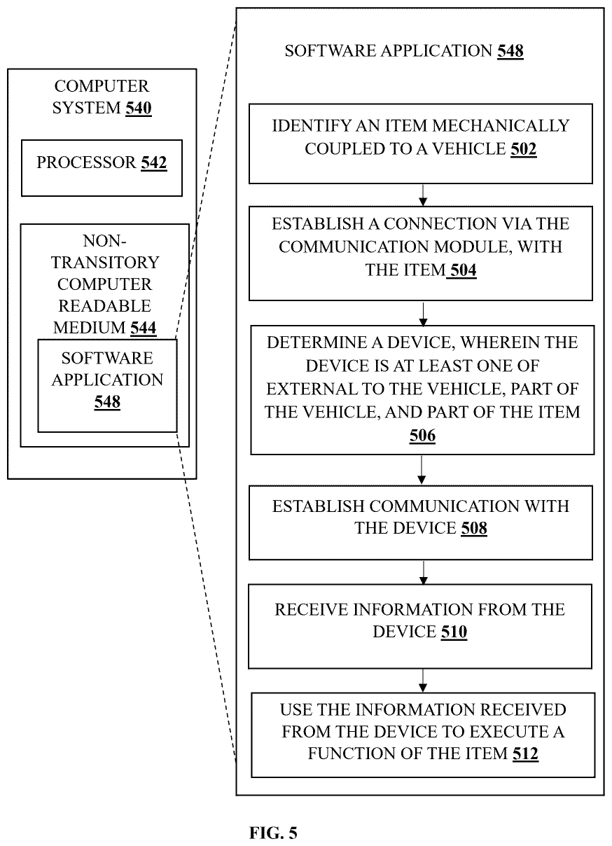

FIG. 5 illustrates a block diagram of the method executed by the non-transitory computer-readable medium according to an embodiment.

According to an embodiment, disclosed is non-transitory computer-readable medium 544 having stored thereon instructions executable by computer system 540 to perform operations comprising: identifying an item mechanically coupled to a vehicle at step 502; establishing a connection with the item at step 504; determining a device, wherein the device is at least one of external to the vehicle, part of the vehicle, and part of the item at step 506; establishing communication with the device at step 508, receiving information from the device at step 510; and using the information received from the device to execute a function of the item at step 512. A software application 548 may be stored on non-transitory computer-readable medium 544 and executed by processor 542 of computer system 540.

In an embodiment, non-transitory computer-readable medium 544 further comprises instructions to perform operations comprising: identifying a space requirement for the function of the item; determining the device based on the space requirement; and establishing communication with the device. In an embodiment, non-transitory computer-readable medium 544 further comprises instructions to perform operations comprising transmitting the information from the device to a display system; generating a contact free zone based on the information; displaying a map on a display system, wherein the contact free zone is highlighted on the map; and executing the function of the item based on the map. In an embodiment, non-transitory computer-readable medium 544 further comprises instructions to perform operations comprising: determining from the information of the device a dimension of the item; determining from the information a dimension of the space requirement; transmitting the dimension of the item and the dimension of the space requirement to a display system; and displaying the dimension of the item and the dimension of the space requirement as an overlay map on the display system to execute the function of the item. In an embodiment, non-transitory computer-readable medium 544 further comprises instructions to perform operations comprising: determining from the plurality of devices, at least one device required in real time to execute the function of the item, and obtaining the information from the device by enhancing a feature of the device.

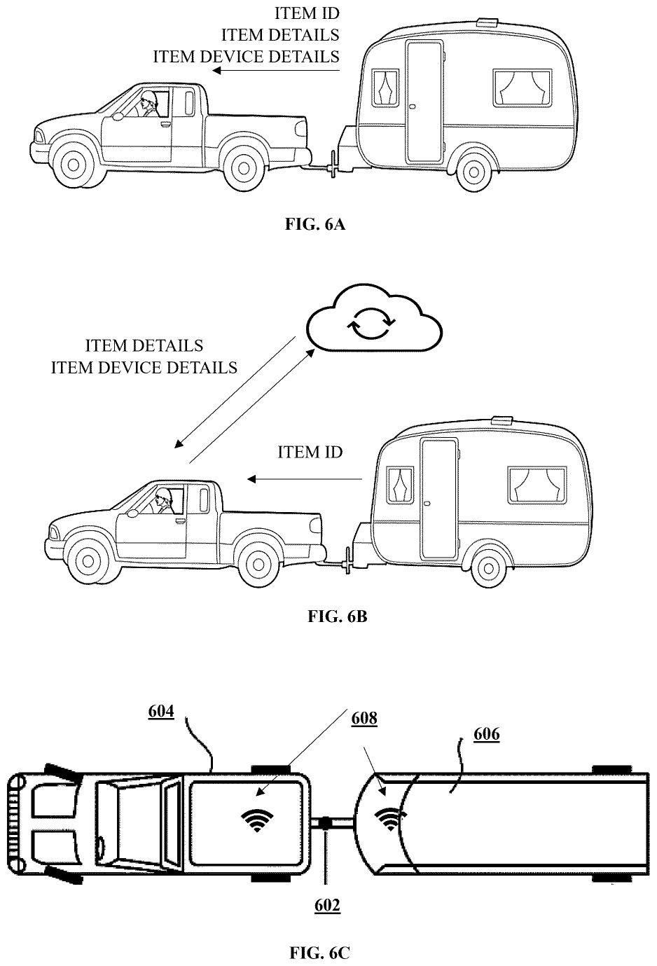

FIG. 6A shows the vehicle obtaining the item or attachment details and cargo details from the item itself according to an embodiment. In an embodiment, the attachment and item details can be directly obtained from the item or attachment itself as shown in FIG. 6A. The item may be a trailer fitted with a Radio Frequency Identification Chip (RFID). The RFID may contain identification and additional details pertaining to the item or attachment such as the devices of the item, their functionalities, technologies it is fitted with, etc. RFID tags or transponders attached to the item or trailer contain a unique identifier and sometimes additional data. These tags are equipped with an antenna that communicates with RFID readers using radio frequency signals. When an RFID tag comes within the range of an RFID reader, which is attached in the vehicle, the reader emits radio waves that power the tag, allowing the RFID tag to transmit its unique identifier back to the reader. The RFID reader then captures the transmitted data and can retrieve additional details or information associated with that particular tag from a database or information system. The details may be password protected and the password may be sent to the user by the RFID tag owner. In an embodiment, the RFID may direct to a website from which additional details may be obtained.

FIG. 6B shows obtaining item details from the cloud network according to an embodiment. According to this embodiment, an RFID tag may be used to obtain an identification number of the item by the vehicle. Using this identification number, the system may obtain the details related to the item or attachment, such as information related to the devices of the item, using a cloud network where the information may be stored.

FIG. 6C shows mechanical coupling 602 connecting the vehicle 604 and the trailer 606. Wireless communication 608 encompasses various technologies that enable the transmission of data without the need for physical wires or cables. According to an embodiment, wireless communication includes Wi-Fi®, Bluetooth®, cellular communication, Radio Frequency Identification (RFID), Near Field Communication (NFC), Satellite communication. These wireless technologies are enabled for seamless connectivity and data sharing.

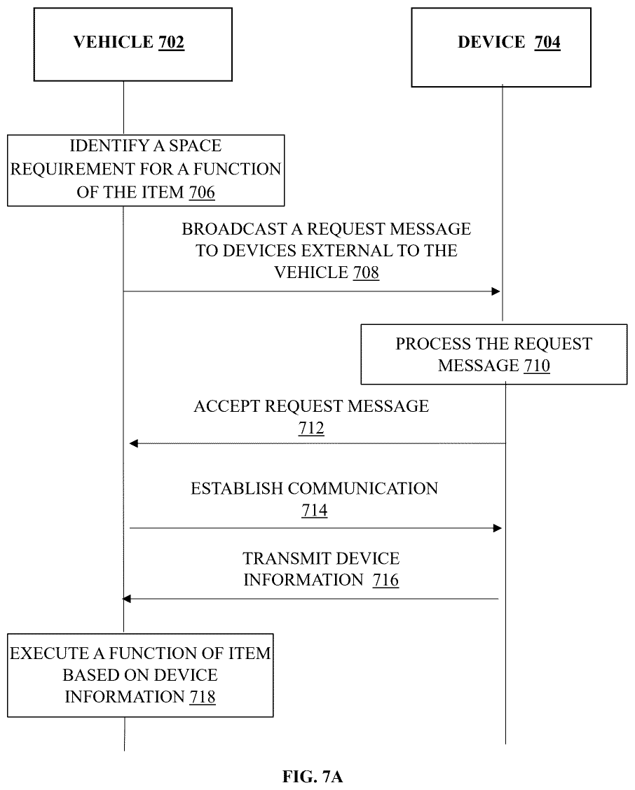

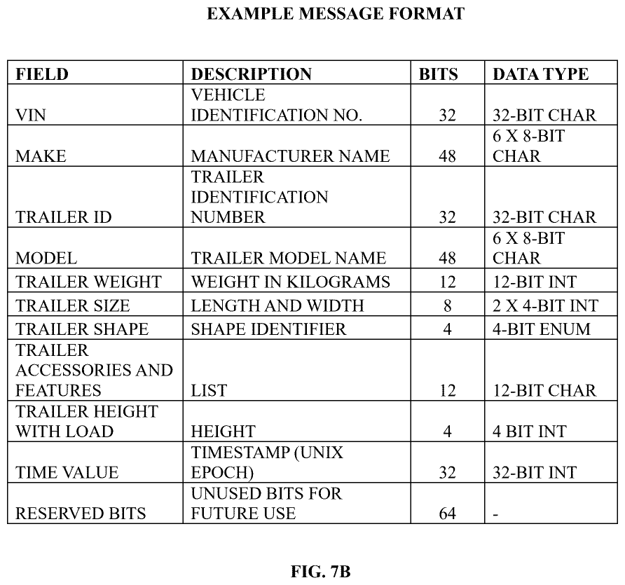

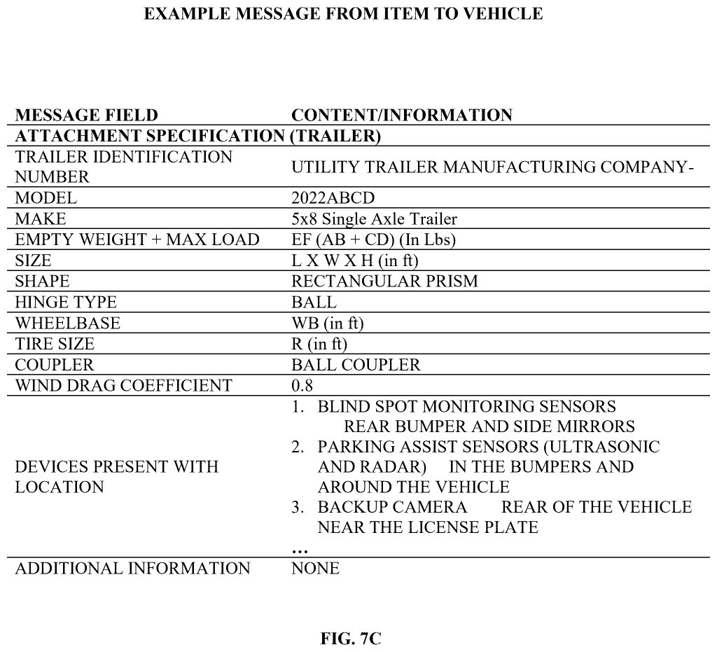

FIG. 7A illustrates a message flow diagram between the vehicle and the device according to an embodiment.

Referring to FIG. 7A, the vehicle 702 in communication with the device 704 is shown. In an embodiment, the device may be one of external to the vehicle, a part of the vehicle, and a part of the item. The vehicle 702 may identify a space requirement to carry out a function of the item at step 706. In an embodiment, the function of the item may be parking the item in a garage. In some embodiments, the vehicle 702 may broadcast a request message to devices external to the vehicle at step 708. In an embodiment, the devices may include sensors located on the back wall of the garage, sensors on the side wall of the garage, and camera on the roof of the garage. The device 704 may process the request message at step 710 and accept the request message at step 712. The vehicle may establish communication with the device at step 714. The device 704 may establish communication with the vehicle at step 714. The vehicle 702 may transmit device information to the vehicle at step 716. The vehicle may execute the function of the item based on the received device information at step 718. In an embodiment, the vehicle may establish communication with the sensors of the garage and receive information, such as images from the cameras of the garage, distance information from proximity sensors, and based on the received information park the item safely in the garage.

FIG. 7B shows an example communication message format and memory allocation according to an embodiment. To prepare a compact message for conveying trailer details and the load/cargo details, a binary encoding scheme, where each item is allocated a specific number of bits, may be used. The number of bits allocated to each item will depend on the range and precision required for that particular attribute. FIG. 7B shows an example field and allocation of bits according to an embodiment. In this example, each field in the message has a specific number of bits allocated to it:

Vehicle Identification Number (VIN) field uses 32 bits (32 characters, each represented by an 8-bit ASCII code) to represent the Vehicle Identification Number, a unique identifier for the trailer. The item make uses 48 bits (6 characters, each represented by an 8-bit ASCII code) to specify the manufacturer's name. Model uses 48 bits (6 characters, each represented by an 8-bit ASCII code) to specify the item's model name.

Trailer Size field uses 8 bits (4 bits for length and 4 bits for width) to represent the trailer's size in meters or feet. The Trailer Shape field uses 4 bits to represent a shape identifier, where different shape codes can be assigned to various trailer shapes (e.g., rectangular, rounded, etc.). The Trailer Weight field uses 12 bits to represent the trailer's weight in kilograms, accommodating a range of weight values.

Trailer Accessories and Features uses 12 bits (character) and may comprise accessories and additional features coded as a string with identifiers for sensors and locations, accessories present, etc.

The Time Value field uses 32 bits to represent the timestamp using Unix Epoch format, indicating when the message was generated. The Reserved Bits are bits set aside for potential future use or additional attributes that may be added to the message format later.

Message fields and allocation of bits are, for example, a hypothetical representation for demonstration. In implementations, the fields, actual message format, and the number of bits allocated to each item may vary based on the specific requirements and constraints of the application and communication protocol used.

Various communication protocols can be employed for transmitting trailer details based on specific application requirements and range considerations. Bluetooth® and Wi-Fi® are suitable for short-range communication within close proximity, while cellular communication utilizing 3G, 4G, or 5G networks allows for data transfer over longer distances. RFID is valuable for contactless identification or tracking purposes, and CAN may be used for in-vehicle communication between the trailer and the vehicle. V2X protocols encompass V2V and V2I communication, enabling vehicles to share data with each other and infrastructure units. DSRC, designed for V2V and V2I scenarios, facilitates short-range communication of trailer details. The selection of the communication protocol depends on factors such as range, data transfer rate, power consumption, security, and existing infrastructure, as well as the specific use case for trailer details communication.

Once the communication link is established, the information related to the specification of the trailer gets transmitted. The specification of the trailer is transmitted via a message. The message comprises one or more of a Vehicle (Trailer) Identification Number (VIN), a height of the trailer, a length of the trailer, a weight of the trailer, a make and model of the trailer, a wheelbase, a payload, number of trailer wheels, and devices of the trailer.

In an embodiment, icons on a graphical user interface (GUI) or display of the infotainment system of a computer system are re-arranged based on a priority score of the content of the message. The processor tracks the messages that need to be displayed at a given time and generates a priority score, wherein the priority score is determined based on the action that needs to be taken by the user, the time available before the user input is needed, content of the message to be displayed, criticality of the user's input/action that needs to be taken, the sequence of the message or messages that need to be displayed and executed, and the safety of the overall scenario. The priority of the messages are evaluated dynamically as the situation is evolving and thus the display icons, positions, and sizes of the text or icon on the display are changed in real time and dynamically. In an embodiment, more than one message is displayed and highlighted as per the situation and the user's actions

FIG. 7C shows an example message exchange between trailer and the vehicle according to an embodiment. It may comprise elements that relate to the trailer and its specifications. Trailer specifications may comprise trailer identification number, trailer model, trailer make, and trailer details comprising an empty weight, max load carriable, a size, a shape, a hinge type or coupling mode, wheelbase, tire size, a coupler type, a wind drag coefficient and a list of devices of the item and their location. In an embodiment, the message can be sent to the vehicle upon attachment. In an embodiment, the message may be sent to an App when the trailer is booked or scheduled. In an embodiment, the message may be in the RFID tag and can be read when a reader scans the RFID tag. In an embodiment, the message may be sent to an App on a mobile device.

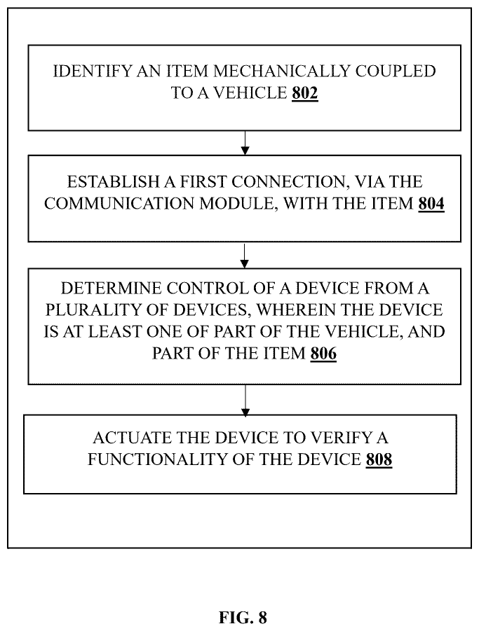

FIG. 8 illustrates a flow chart describing a method of testing functionalities of the devices when an item is attached to the vehicle according to an embodiment.

In some embodiments, the method shown in FIG. 8 may be carried out by a processor using instructions stored in a memory that, when executed, cause the processor to carry out the method. In an embodiment, the method as shown in FIG. 8 may be performed by system 100 as shown in FIG. 1.

Referring to FIG. 8, the method may, at step 802, identify an item mechanically coupled to a vehicle. Method may, at step 804, establish a first connection, via the communication module, with the item. The method may, at step 806, determine control of a device from a plurality of devices, wherein the device is at least one of part of the vehicle, and part of the item. The method may, at step 808, actuate the device to verify a functionality of the device.

In an embodiment, the method may further create a test schedule to verify the functionality of each of the plurality of devices individually, and actuate each of the devices based on the test schedule. In an embodiment, the method may establish a second connection with an external device; and actuate the device based on an instruction received from the external device. In an embodiment, the external device may comprise at least one of a key fob, a key card, a voice actuated device, a wearable device, and a mobile device. In an embodiment, the method may interpret an external device signal as actuating the device when the external device is in proximity to the device. The method may transmit a result of the actuation of the device to a display system; store the result in a database, retrieve the result from the database; perform a historical analysis of a device performance based on the result; and predict a malfunction of the device. In an embodiment, the method may generate a machine learning model; obtain information from the device; and transmit the information to the machine learning model, wherein the machine learning model is configured to predict based on the information, a malfunction of the device.

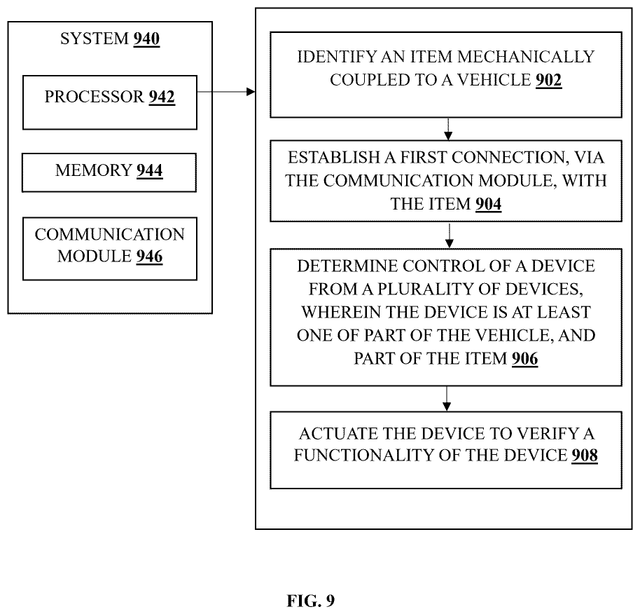

FIG. 9 illustrates a block diagram of the system implementing the method according to an embodiment. According to an embodiment, disclosed is system 940 comprising processor 942, memory 944, and communication module 946, wherein memory 944 storing processor-executable instructions, which on execution, cause the processor to: identify an item mechanically coupled to a vehicle at step 902, establish a first connection, via the communication module, with the item at step 904, determine control of a device from a plurality of devices, wherein the device is at least one of part of the vehicle, and part of the item at step 906, and actuate the device to verify a functionality of the device at step 908.

In an embodiment, the processor-executable instructions, which on execution, cause the processor to create a test schedule to verify the functionality of each of the plurality of devices individually; and actuate each of the devices based on the test schedule. In an embodiment, the system may establish a second connection with an external device; and actuate the device based on an instruction received from the external device. In an embodiment, the external device may comprise at least one of a key fob, a key card, a voice actuated device, a wearable device, and a mobile device. In an embodiment, the processor-executable instructions, which on execution, cause the processor to interpret an external device signal as actuating the device when the external device is in proximity to the device. The system may transmit a result of the actuation of the device to a display system, store the result in a database, retrieve the result from the database, perform a historical analysis of a device performance based on the result, and predict a malfunction of the device. In an example, the result may be stored with device identification, test case, date, time, location, and test result details. In an embodiment, the method may generate a machine learning model, obtain information from the device, and transmit the information to the machine learning model; and wherein the machine learning model is configured to: predict based on the information, a malfunction of the device.

In an embodiment, when the driver attaches an attachment, such as a trailer, the driver needs to check to make sure all the lights work as expected. In addition, if the trailer has sensors and cameras, the system may verify their operation upon connection. The system can create a pattern or allow the user to individually test each device. The driver can walk to the light or turn signal and through the system actuate the device to verify its operation. In an aspect, once the user attaches a trailer to a vehicle, the system establishes a communication with the trailer and takes control of its devices, such as lights, sensors and cameras. The system may further establish communication with one or more devices e.g., mobile device or a key FOB to use for testing. As used herein, a “key fob” refers to an electronic device that wirelessly communicates with the vehicle (e.g., via the communication module) to unlock and/or lock one or more of the doors, open and/or close one or more of the doors, and/or activate the engine of the vehicle. According to an embodiment, the user now can approach a light, sensor or camera to test, and actuate the test. In an aspect, the user may provide a voice commands (e.g., “test the rear left light” or “test the right side camera”). In an aspect, the user may stand near the light to be tested and actuate the test via an app or pressing a button on the key FOB, e.g., when in testing mode, any button on the key FOB can be used and the system may interpret the key FOB signal as testing the device near the key FOB. Thus, the user can stand next to the light and test it. Once tested, the user can walk over to the next device. In another embodiment, the user may provide voice commands (e.g., “test rear left turn signal” or “test left sensor”) without having to stand next to the device.

In an embodiment, a test schedule may be based on vehicle identification (VIN), vehicle mileage, or sensor error codes logged by the controller and provides an opportunity for dynamic testing of many of the sensors of the vehicle and the item. If the sensor information indicates that one or more of the sensors fails to operate within the designated tolerances, the vehicle is instructed to operate in a reduced sensor capacity. In an embodiment, if the sensor information indicates a sensor failure or malfunction that would impair autonomous control of the vehicle, the vehicle is instructed to operate in manual mode. The system receives the sensor information and/or any analytical information generated by the controller related to the unexpected sensor performance for further analysis. In an embodiment, the information is analyzed within the vehicle controller. In another embodiment, the information is transmitted by the communication module to the analysis and recommendation module for analysis and comparison with expected or historical sensor data.

The system may continue with a series of steps, a test schedule, that are designed to generate a verification of individual devices on vehicle trailer combinations. The test schedule may be operable through the vehicle display system or a user device. The system may determine whether the vehicle trailer combination generates data indicative of operating characteristics for a given device of vehicle trailer combination. If the vehicle trailer combination does not generate data regarding a device for which verification is required or desirable or when a manual verification of the device by the driver is desirable, the method may display on the user device an instruction to the driver to perform a task associated with the verification of the device. The instruction may, for example, comprise an instruction to the driver to enter data or information about a device of vehicle trailer combination through a graphical user interface on the user device. The instruction may comprise an instruction to the driver to capture an image or a video of a functioning of a device through another device, such as a camera. The instruction may comprise an instruction to capture an image of the operation of a turn signal of the vehicle trailer combination. The instruction may comprise an instruction to the operator to capture an audio recording of a device, for example, instruct the driver to capture an audio recording of a horn on vehicle trailer combinations. Each instruction may include multiple steps including steps that direct the driver to perform a physical movement (e.g., activating a turn signal or sounding a horn). Each instruction may further include a variety of information relating to the instruction including the location of the device, the reasons a verification is necessary or desirable, etc. The information is stored in a database for future analysis and prediction of a malfunction of the device. In the case of a verification due to a suspected failure of a specific device, the driver may indicate that the verification will be limited to one or more specific devices, through the interface on the user device. The system is configured to transmit a verification report to the user device.

In an embodiment, the system may be configured to monitor the location of the driver relative to the location of the vehicle as the verification is performed to ensure a proper verification of the device. In an embodiment, a user device may monitor the location of the driver by monitoring the position of the user device using a GPS receiver on the user device in order to ensure that the verification is being completed in a predetermined order and/or within a predetermined time frame. User device may be further configured to determine whether the location of the driver meets a predetermined condition (e.g., is at a predetermined location, is at a predetermined distance from the vehicle and/or has traveled over a predetermined distance and/or within a predetermined time) and, when the location does not meet the predetermined condition (thereby indicating a failure to perform some aspect of the verification), an instruction is transmitted to one of the vehicle control systems.

In an embodiment, the communication module of the vehicle may detect when a key fob of the user that is associated with the vehicle is near the vehicle. The vehicle system includes accelerometer(s) positioned on window(s) of the vehicle that enable the window(s) to function as microphone(s). The accelerometer(s) are activated to receive signal(s) when the communication module detects that the key fob is nearby. The accelerometer(s) sends the received signal(s) to a controller for speech recognition analysis. The controller is configured to identify a wake-up indicator and a subsequent command within the signal(s). In an example, the user is carrying the key fob for wireless communication with the communication module. In other examples, the user carries a mobile device functioning as a phone-as-a-key for wireless communication with the communication module. As used herein, a “phone-as-a-key” refers to a mobile device (e.g., a smart phone, a wearable, a smart watch, a tablet, etc.) that includes hardware and/or software to function as a key fob.

Prior to communicating with the key fob, the communication module may be utilized to authenticate the key fob for communication with the communication module. Upon being authenticated, the key fob is paired with the vehicle. For example, to authenticate the key fob, the communication module intermittently broadcasts a beacon (e.g., a low-energy beacon such as Bluetooth® low-energy (BLE) beacon). When the key fob is within a broadcast range of the vehicle, the key fob receives the beacon and subsequently sends a key. The communication module authenticates the key fob for communication upon receiving the key from the key fob. In other examples, the key fob broadcasts a beacon, and the communication module subsequently receives the beacon to authenticate communication between the key fob and the communication module.

The vehicle also includes vibration sensors that are coupled to the outer layer of the vehicle to detect audio vibrations. The vibration sensors may be configured to measure audio vibrations of portions of the outer layer of the vehicle to which the vibration sensors are coupled. Further, the vibration sensors may be configured to measure a wide frequency range of sound, for example, to enable detection of voice commands provided by the user. The verification of the devices of the vehicle item combination may be carried out by voice commands from the user. In operation, a voice command controller utilizes signals retrieved from the vibration sensors to detect a voice command that has been provided by the user. For example, the voice-command controller and the vibration sensors are configured to detect voice command(s) that are provided by the user when the user is located outside of, but near, the vehicle. For example, to identify a voice command, the voice command controller initially receives an audio signal that is detected via one or more of the vibration sensors. The voice command controller subsequently utilizes voice recognition (e.g., via voice-recognition software) to identify a word or phrase within the audio signal and compares that word or phrase to a set of commands or requests (e.g., stored in a database) that correspond with the vehicle. If the identified word or phrase corresponds to one of the predefined commands or requests, the voice command controller detects a voice command within the audio signal detected via one or more of the vibration sensors.

In some examples, the vibration sensors are triggered to detect a voice command of the user. For example, the voice-command controller triggers the vibration sensors to detect the voice command responsive to the voice-command controller identifying, via one or more of the vibration sensors, that the user has provided a wake-up term that precedes the voice command. That is, the user is to provide the wake-up term prior to providing the voice command to trigger detection of the voice command. The wake-up-word can be any word or phrase preselected by the manufacturer or the driver, such as a word, a name, and/or a phrase. For example, to identify the wake-up term, the voice-command controller initially receives an audio signal that is detected via one or more of the vibration sensors. The voice-command controller subsequently utilizes voice recognition (e.g., via voice-recognition software) to identify a word or phrase within the audio signal and compares that word or phrase to a predefined wake-up term (e.g., stored in the database) that corresponds with the vehicle. Upon identifying that the audio signal includes the predefined wake-up term, the voice-command controller triggers the vibration sensors to detect a voice command that follows the wake-up term.

In an embodiment, the voice command controller may be configured to detect a distance between the key fob and the vehicle based upon the received signal strength indicator(s) (RSSI) of signal(s) between the key fob and the communication module. In an embodiment, the voice command controller determines whether the detected wake-up term and/or voice command was provided by an authorized source. For example, the voice command controller confirms that the wake-up term and/or voice command was provided by the user that is carrying the key fob paired with the vehicle. Further, in some examples, the voice command controller determines which of the vibration sensors to activate for detecting the wake-up term and/or voice command based upon the identified location of the key fob. For example, the voice-command controller activates one or more of the vibration sensors located toward the vehicle's front side upon detecting that the key fob is located in front of the vehicle. In response to the voice command controller determining that the voice command is an instruction to perform a vehicle function, the voice command controller identifies the vehicle function to be performed and sends a signal to perform the identified vehicle function.

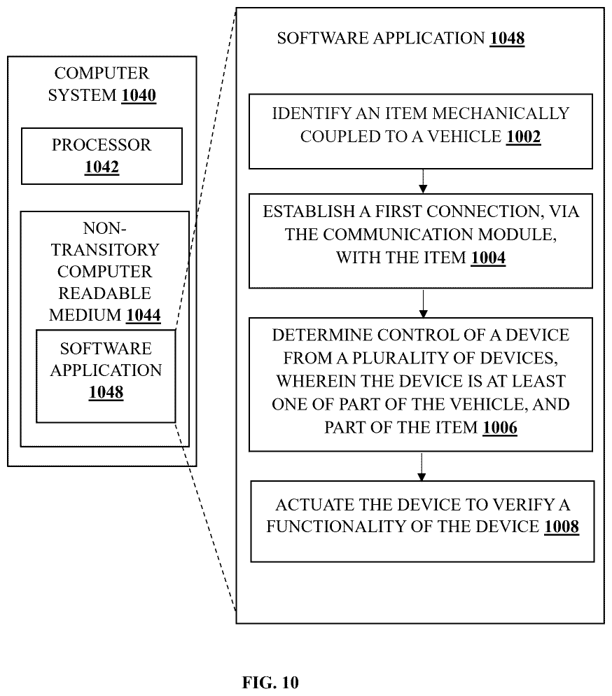

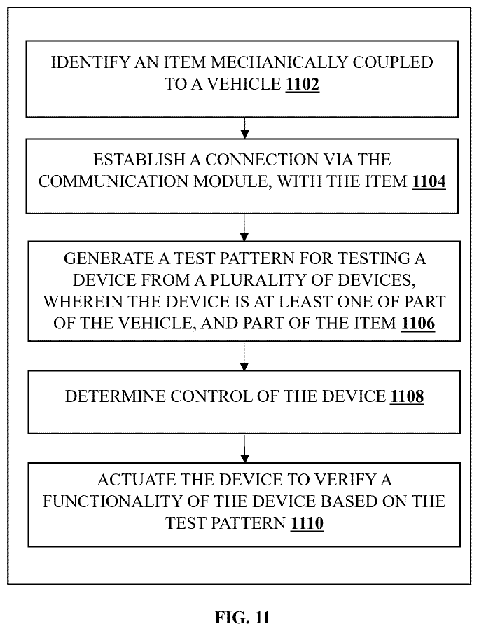

FIG. 10 illustrates a block diagram of the method executed by the non-transitory computer-readable medium according to an embodiment.

According to an embodiment, disclosed is a non-transitory computer-readable medium 1044 having stored thereon instructions executable by computer system 1040 to perform operations comprising: identifying an item mechanically coupled to a vehicle at step 1002; establishing a first connection via a communication module, with the item at step 1004; determining control of a device from a plurality of devices, wherein the device is at least one of part of the vehicle, and part of the item at step 1006; and actuating the device to verify a functionality of the device at step 1008. A software application 1048 may be stored on non-transitory computer-readable medium 1044 and executed by processor 1042 of computer system 1040.

In an embodiment, non-transitory computer-readable medium 1044 further comprises instructions to perform operations comprising creating a test schedule to verify the functionality of each of the plurality of devices individually; and actuating each of the devices based on the test schedule. In an embodiment, non-transitory computer-readable medium 1044 further comprises instructions to perform operations comprising establishing a second connection with an external device; and actuating the device based on an instruction received from the external device. In an embodiment, non-transitory computer-readable medium 1044 further comprises instructions to perform operations comprising interpreting an external device signal as actuating the device when the external device is in proximity to the device. In an embodiment, non-transitory computer-readable medium 1044 further comprises instructions to perform operations comprising transmitting a result of the actuation of the device to a display system, storing the result in a database, retrieving the result from the database, performing a historical analysis of a device performance based on the result, and predicting a malfunction of the device.

FIG. 11 illustrates a flow chart describing a method testing functionalities of the devices when an item is attached to the vehicle according to an embodiment.

In some embodiments, the method shown in FIG. 11 may be carried out by a processor using instructions stored in a memory that, when executed, cause the processor to carry out the method. In an embodiment, the method as shown in FIG. 11 may be performed by system 100 as shown in FIG. 1.

Referring to FIG. 11, the method may, at step 1102, identify an item mechanically coupled to a vehicle. Method may, at step 1104, establish a first connection, via the communication module, with the item. The method may, at step 1106, generate a test pattern for testing a device from a plurality of devices, wherein the device is at least one of part of the vehicle, and part of the item. The method may, at step 1108, determine control of the device. The method may, at step 1110, actuate the device to verify a functionality of the device based on the test pattern.

In an embodiment, the method may update the test pattern to verify the functionality of each of the plurality of devices individually; and actuate each of the devices based on the test pattern. In an embodiment, the test pattern comprises at least one of a sequential test pattern, an overall test pattern, a selective test pattern, a detailed test pattern, a small test pattern, a speed based test pattern, and a priority based test pattern. In an embodiment, the method may transmit the test pattern to an external device; and actuate the device of the item based on an instruction received from the external device. In an embodiment, the method may update in real time a starting point of the test pattern based on the proximity of the external device from the device. In an embodiment, the method may transmit a result of actuation of the device to a display system, store the result in a database, retrieve the result from the database, perform a historical analysis of a device performance based on the result, and predict a malfunction of the device.

In an embodiment, the system may create an automated test pattern to verify the functionality of the devices of the vehicle and the devices of the item. In an example, when the driver closes the door, and starts to step out, the system informs the driver through an application on a user device, that the test pattern is created. In this case the user need not mention each device to be tested but the test pattern may create a test pattern based on proximity of the driver. In an example, in case the driver moves to the front of the vehicle, an automated test pattern of the devices is created that starts at the front of the vehicle. In an embodiment, the speed of the execution of the test pattern may be adjusted by the driver. In another embodiment, the speed of the execution of the test pattern may be adjusted based on the speed of movement of the driver around the vehicle and the item. The system may dynamically update the test pattern based on the movement and the speed of movement of the user around the vehicle and the item. The test pattern may be restarted by the driver at any point during the execution of the test pattern. The pattern may be a sequential pattern that carries out the testing of the devices in a predefined manner or a dynamically generated sequence. The testing time of a device may also be added to the test pattern. In an embodiment, the test pattern may be a smaller pattern that's just for the front, or the sides. Further, there may be multiple test patterns for the sides. The test pattern may be executed from a predefined distance from the vehicle. The user may move around or stay still, the test pattern will continue testing all of the functionality that is visible to the user.

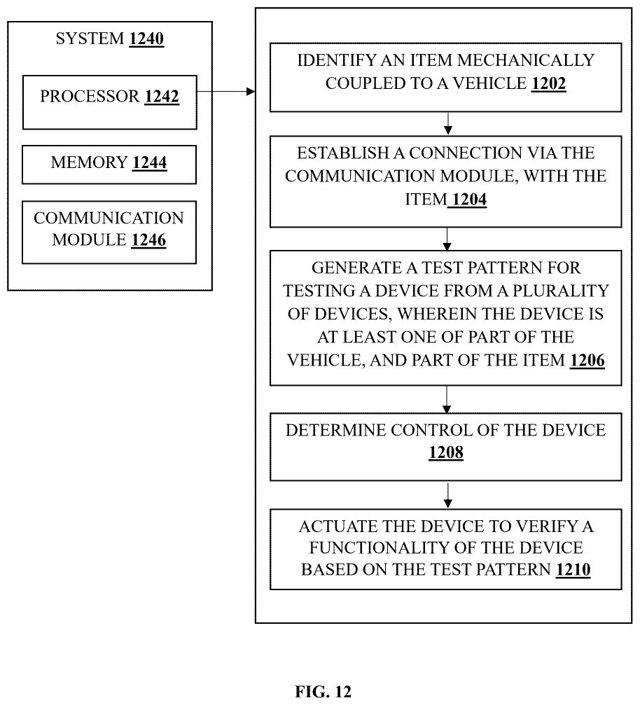

FIG. 12 illustrates a block diagram of the system implementing the method according to an embodiment. According to an embodiment, disclosed is system 1240 comprising processor 1242, memory 1244, and communication module 1246, wherein the memory 1244 storing processor-executable instructions, which on execution, cause the processor to: identify an item mechanically coupled to a vehicle 1202, establish a first connection, via the communication module, with the item 1204, generate a test pattern for testing a device from a plurality of devices, wherein the device is at least one of part of the vehicle, and part of the item 1206, determine control of the device 1208, and actuate the device to verify a functionality of the device based on the test pattern 1210.

In an embodiment of the system, the processor-executable instructions, which on execution, cause the processor to update the test pattern to verify the functionality of each of the plurality of devices individually, and actuate each of the devices based on the test pattern. In an embodiment, the test pattern comprises at least one of a sequential test pattern, an overall test pattern, a selective test pattern, a detailed test pattern, a small test pattern, a speed based test pattern, and a priority based test pattern. In an embodiment, the processor-executable instructions, which on execution, cause the processor to transmit the test pattern to an external device, and actuate the device of the item based on an instruction received from the external device. In an embodiment, the processor-executable instructions, which on execution, cause the processor to update in real time a starting point of the test pattern based on the proximity of the external device from the item's device. In an embodiment, the processor-executable instructions, which on execution, cause the processor to transmit a result of actuation of the device to a display system, store the result in a database, retrieve the result from the database, perform a historical analysis of a device performance based on the result, and predict a malfunction of the device. In an embodiment, the processor-executable instructions, which on execution, cause the processor to generate a machine learning model, transmit the test pattern to the machine learning model, and wherein the machine learning model is configured to predict an optimized test pattern to actuate the device to verify the functionality of the device.

In another embodiment, the system may create a test pattern to test the external devices (e.g., brake lights, sensors, cameras or turn signals) of the vehicle and the attached item. In an aspect, the user may attach a trailer to the vehicle. The vehicle may be alerted that something is attached to it. A wire/wireless communication link is established with the attachment. The features of the attachments are communicated to the vehicle system. The vehicle may generate a test pattern to test the lights, sensors, and cameras. The user may be alerted that the test pattern is ready and provided as a display on the user's device. The user, when ready, can actuate the test pattern. Once the test pattern is actuated, the system guides the user to verify each item by displaying on the user device and actuating the functionality of the tested item (e.g., brake light or turn signal). For the sensors, the system generates a new contact free zone (e.g., a zone established using the sensors such that if something is inside that zone, an alert is provided). The new contact free zone would include the trailer. The system can request the user to enter the contact free zone to test the sensors and cameras.

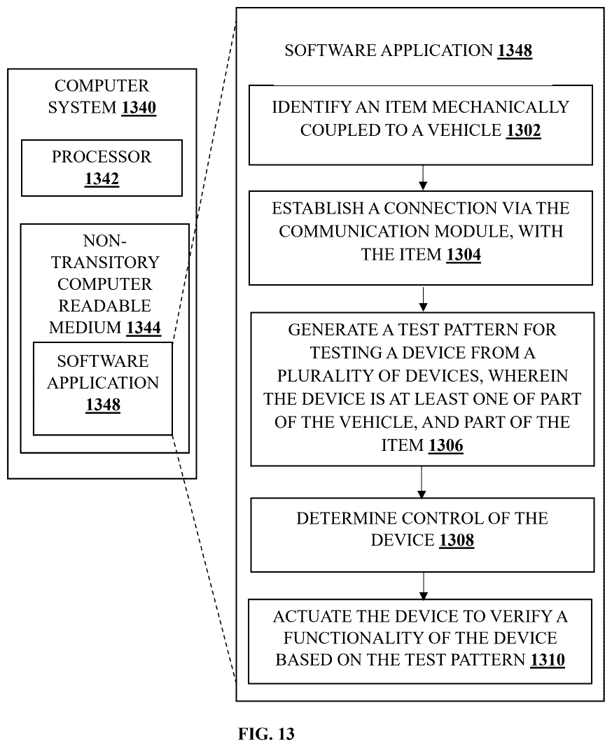

FIG. 13 illustrates a block diagram of the method executed by the non-transitory computer-readable medium according to an embodiment.

According to an embodiment, disclosed is non-transitory computer-readable medium 1344 having stored thereon instructions executable by computer system 1340 to perform operations comprising: identifying an item mechanically coupled to a vehicle at step 1302; establishing a first connection via a communication module, with the item at step 1304; generating a test pattern for testing a device from a plurality of devices, wherein the device is at least one of part of the vehicle, and part of the item at step 1306; determining control of the device at step 1308, and actuating the device to verify a functionality of the device based on the test pattern at step 1310. A software application 1348 may be stored on non-transitory computer-readable medium 1344 and executed by processor 1342 of computer system 1340.

In an embodiment, non-transitory computer-readable medium 1344 further comprises instructions to perform operations comprising updating the test pattern to verify the functionality of each of the plurality of devices individually and actuating each of the devices based on the test pattern. In an embodiment, non-transitory computer-readable medium 1344 further comprises instructions to perform operations comprising transmitting the test pattern to an external device and actuating the device of the item based on an instruction received from the external device. In an embodiment, non-transitory computer-readable medium 1344 further comprises instructions to perform operations comprising actuating the device based on proximity of the external device from the device. In an embodiment, non-transitory computer-readable medium 1344 further comprises instructions to perform operations comprising updating in real time a starting point of the test pattern based on the proximity of the external device from the device. In an embodiment, non-transitory computer-readable medium 1344 further comprises instructions to perform operations comprising transmitting a result of actuation of the device to a display system, and storing the result in a database, retrieving the result from the database, performing a historical analysis of a device performance based on the result, and predicting a malfunction of the device.

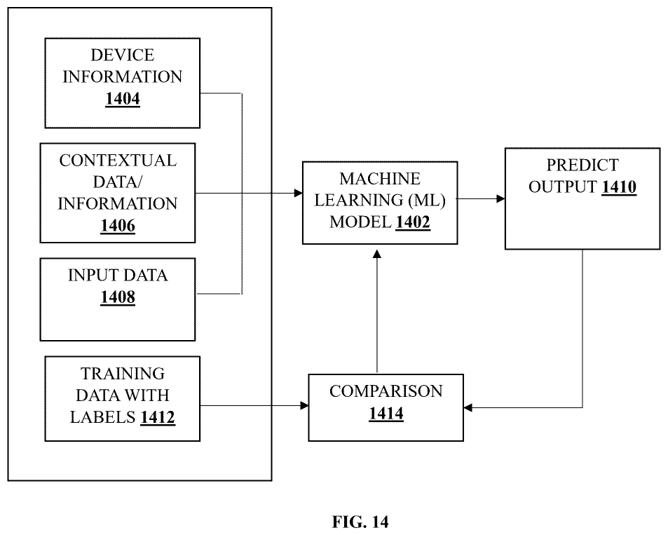

FIG. 14 illustrates an example block diagram for an Artificial Intelligence and Machine Learning (AI/ML) model used in a system according to an embodiment.

Referring to FIG. 14, the machine learning model 1402 may take as input any data associated with a device information 1404, contextual data/information 1406, and function information as the input data 1408 and learn to identify from the available devices, a set of devices that may provide an optimized method to execute a function of the item. The contextual data/information 1406 may include environmental factors, historical factors that may affect carrying out the function of the item. Training data with labels 1412 may comprise, for example, a historical data of devices selected to carry out a particular function. The systems and methods of the present disclosure may also provide data analytics information that may be used later to improve the prediction accuracy of identifying the devices in an optimized way to carry out a function of the item.

In an embodiment, during training, machine learning model 1402 may process the training data sample (e.g., device information 1404, contextual data/information 1406, and function information as the input data 1408), and, based on the current parameters of machine learning model 1402, predict output 1410 which may be an optimized method to execute a function of the item. In an embodiment, the real-time sensor data may be processed using one or more machine learning models 1402, trained and based on similar types of data to correctly estimate the devices needed to execute a function of the item, and correctly estimate the devices needed to execute a function of the item in a given condition, such as in a particular environmental condition, for example, rainy weather or snowy weather. For example, comparison 1414 may be based on a loss function that measures a difference between the predicted/detected output and training data with labels 1412. Based on the comparison 1414 or the corresponding output of the loss function, a training algorithm may update the parameters of machine learning model 1402 with the objective of minimizing the differences or loss between subsequent predicted output 1410 and corresponding labels 1412. By iteratively training in this manner, machine learning model 1402 may “learn” from the different training data samples and become better at predicting output 1410. In an embodiment, machine learning model 1402 is trained using data which is specific to a function of the item for which the model is used for predicting adjustments to the settings to provide accurate estimation of the devices needed to execute a function of the item. In an embodiment, machine learning model 1402 is trained using data which is general to the different functions of the item and is used for predicting adjustments for prediction of the devices needed to execute a function of the item. In an embodiment, the device information may be given weights and provided as an input to the AI/ML system.

Through training, machine learning model 1402 may learn to identify predictive and non-predictive features and apply the appropriate weights to the features to optimize predictive accuracy of machine learning model 1402. In embodiments where supervised learning is used and each training data sample has a label, the training algorithm may iteratively process each training data sample and generate a predicted output 1410. Any suitable machine learning model and training algorithm may be used, including, e.g., neural networks, decision trees, clustering algorithms, and any other suitable machine learning techniques. Once trained, machine learning model 1402 may take input data and detect the objects along with their corresponding confidence score. In an embodiment, machine learning model 1402 is an artificial neural networks (ANN) model.

In an embodiment, during training, machine learning model 1402 may process the training data sample (e.g., device information 1404, contextual data/information 1406, and malfunction information as the input data 1408), and, based on the current parameters of machine learning model 1402, predict output 1410 which may be an optimized method to predict a malfunction of a device of the vehicle and a device of the item. In an embodiment, the real-time sensor data may be processed using one or more machine learning models 1402, trained and based on similar types of data to correctly estimate the malfunction of a device and accordingly take corrective action. For example, comparison 1414 may be based on a loss function that measures a difference between the predicted/detected output and training data with labels 1412. Based on the comparison 1414 or the corresponding output of the loss function, a training algorithm may update the parameters of machine learning model 1402 with the objective of minimizing the differences or loss between subsequent predicted output 1410 and corresponding labels 1412. By iteratively training in this manner, machine learning model 1402 may “learn” from the different training data samples and become better at predicting output 1410. In an embodiment, machine learning model 1402 is trained using data which is specific to a malfunction of a device for which the model is used for predicting adjustments to the settings to provide accurate estimation of the malfunction of a device. In an embodiment, machine learning model 1402 is trained using data which is general to the different malfunctions of the devices and is used for predicting adjustments for prediction of the malfunction of devices. In an embodiment, the device information may be given weights and provided as an input to the AI/ML system.

In an embodiment, during training, machine learning model 1402 may process the training data sample (e.g., device information 1404, contextual data/information 1406, and test pattern information as the input data 1408), and, based on the current parameters of machine learning model 1402, predict output 1410 which may be an optimized method to execute a test pattern of the devices of the vehicle and the devices of the item. In an embodiment, the real-time sensor data may be processed using one or more machine learning models 1402, trained and based on similar types of data to correctly estimate an optimized test pattern to test the devices. For example, comparison 1414 may be based on a loss function that measures a difference between the predicted/detected output and training data with labels 1412. Based on the comparison 1414 or the corresponding output of the loss function, a training algorithm may update the parameters of machine learning model 1402 with the objective of minimizing the differences or loss between subsequent predicted output 1410 and corresponding labels 1412. By iteratively training in this manner, machine learning model 1402 may “learn” from the different training data samples and become better at predicting output 1410. In an embodiment, machine learning model 1402 is trained using data which is specific to a test pattern for which the model is used for predicting adjustments to the settings to provide accurate estimation of the test pattern to be used to verify the functioning of the devices. In an embodiment, machine learning model 1402 is trained using data which is general to the different test patterns and is used for predicting adjustments for prediction of an optimized test pattern. In an embodiment, the device information may be given weights and provided as an input to the AI/ML system.

In an embodiment, the machine learning model is configured to learn using labelled data using a supervised learning method, wherein the supervised learning method comprises logic using at least one of a decision tree, a logistic regression, a support vector machine, a k-nearest neighbors, a Naïve Bayes, a random forest, a linear regression, a polynomial regression, and a support vector machine for regression.

In some embodiments, the machine learning model is configured to learn from a real-time data using an unsupervised learning method, wherein the unsupervised learning method comprises logic using at least one of a k-means clustering, a hierarchical clustering, a hidden Markov model, and an apriori algorithm.

In some embodiments, the machine learning model has a feedback loop, wherein an output from a previous step is fed back to the machine learning model in real-time to improve the performance and accuracy of the output of a next step.

In some embodiments, the machine learning model has a feedback loop, wherein the learning is further reinforced with a reward for each true positive of the output of the system.

In some embodiments, the machine learning model comprises a recurrent neural network model.

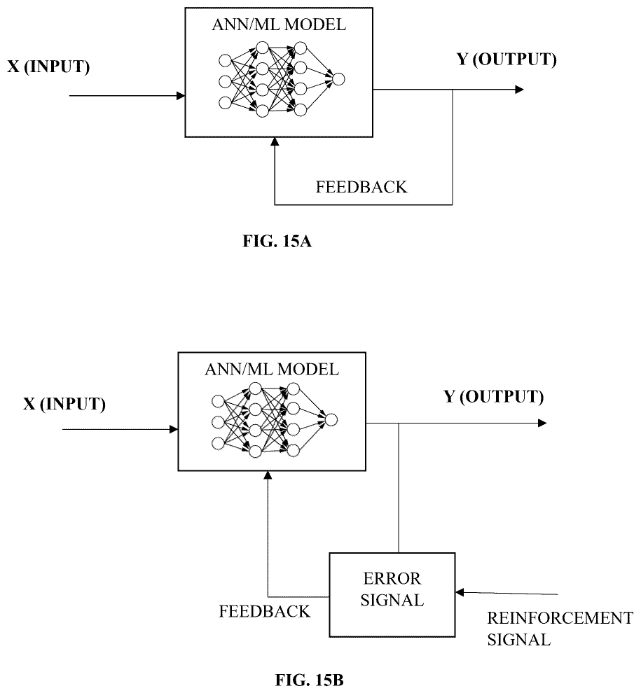

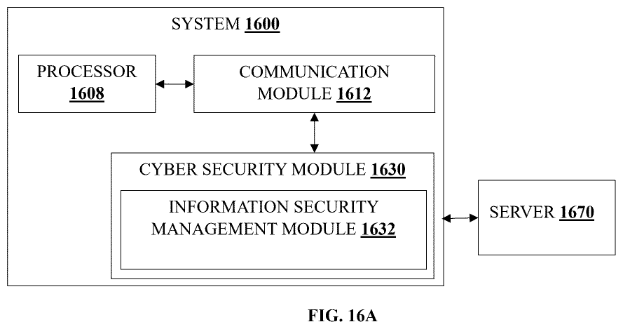

FIG. 15A shows a structure of the neural network/machine learning model with a feedback loop. Artificial neural networks (ANNs) model comprises an input layer, one or more hidden layers, and an output layer. Each node, or artificial neuron, connects to another and has an associated weight and threshold. If the output of any individual node is above the specified threshold value, that node is activated, sending data to the next layer of the network. Otherwise, no data is passed to the next layer of the network. A machine learning model or an ANN model may be trained on a set of data to take a request in the form of input data, make a prediction on that input data, and then provide a response. The model may learn from the data. Learning can be supervised learning and/or unsupervised learning and may be based on different scenarios and with different datasets. Supervised learning comprises logic using at least one of a decision tree, logistic regression, and support vector machines. Unsupervised learning comprises logic using at least one of a k-means clustering, a hierarchical clustering, a hidden Markov model, and an apriori algorithm. The output layer may predict or detect the devices needed to execute a function of the item. In an embodiment, the output layer may predict or detect a malfunction of the device. In another embodiment, the output layer may predict or detect an optimized test pattern to verify the functioning of the devices.

In an embodiment, ANN may be a Deep-Neural Network (DNN), which is a multilayer tandem neural network comprising Artificial Neural Networks (ANN), Convolution Neural Networks (CNN) and Recurrent Neural Networks (RNN) that can recognize features from inputs, do an expert review, and perform actions that require predictions, creative thinking, and analytics. In an embodiment, ANNs may be Recurrent Neural Network (RNN), which is a type of Artificial Neural Networks (ANN), which uses sequential data or time series data. Deep learning algorithms are commonly used for ordinal or temporal problems, such as language translation, Natural Language Processing (NLP), speech recognition, and image recognition, etc. Like feedforward and convolutional neural networks (CNNs), recurrent neural networks utilize training data to learn. They are distinguished by their “memory” as they take information from prior input via a feedback loop to influence the current input and output. An output from the output layer in a neural network model is fed back to the machine learning model through the feedback. The variations of weights in the hidden layer(s) will be adjusted to fit the expected outputs better while training the model. This will allow the model to provide results with far fewer mistakes.

The neural network is featured with the feedback loop to adjust the system output dynamically as it learns from the new data. In machine learning, backpropagation and feedback loops are used to train an AI model and continuously improve it upon usage. As the incoming data that the model receives increases, there are more opportunities for the model to learn from the data. The feedback loops, or backpropagation algorithms, identify inconsistencies and feed the corrected information back into the model as an input.

Even though the AI/ML model is trained well, with large sets of labelled data and concepts, after a while, the models'performance may decline while adding new, unlabelled input due to many reasons which include, but not limited to, concept drift, recall precision degradation due to drifting away from true positives, and data drift over time. A feedback loop to the model keeps the AI results accurate and ensures that the model maintains its performance and improvement, even when new unlabelled data is assimilated. A feedback loop refers to the process by which an AI model's predicted output is reused to train new versions of the model.

Initially, when the AI/ML model is trained, a few labelled samples comprising both positive and negative examples of the concepts (for e.g., execution of a function of the item, prediction or detection of a malfunction of the device, and prediction or detection of an optimized test pattern to verify the functioning of the devices) are used that are meant for the model to learn. Afterward, the model is tested using unlabelled data. By using, for example, deep learning and neural networks, the model can then make predictions on whether the desired concept/s (for e.g., execution of a function of the item, prediction or detection of a malfunction of the device, and prediction or detection of a test pattern to verify the functioning of the devices) are in unlabelled images. Each image is given a probability score where higher scores represent a higher level of confidence in the models'predictions. Where a model gives an image a high probability score, it is auto labelled with the predicted concept. However, in the cases where the model returns a low probability score, this input may be sent to a controller (may be a human moderator) which verifies and, as necessary, corrects the result. The human moderator may be used only in exception cases. The feedback loop feeds labelled data, auto-labelled or controller-verified, back to the model dynamically and is used as training data so that the system can improve its predictions in real-time and dynamically.

FIG. 15B shows a structure of the neural network/machine learning model with reinforcement learning. The network receives feedback from authorized networked environments. Though the system is similar to supervised learning, the feedback obtained in this case is evaluative not instructive, which means there is no teacher as in supervised learning. After receiving the feedback, the network performs adjustments of the weights to get better predictions in the future. Machine learning techniques, like deep learning, allow models to take labelled training data and learn to recognize those concepts in subsequent data and images. The model may be fed with new data for testing, hence by feeding the model with data it has already predicted over, the training gets reinforced. If the machine learning model has a feedback loop, the learning is further reinforced with a reward for each true positive of the output of the system. Feedback loops ensure that AI results do not stagnate. By incorporating a feedback loop, the model output keeps improving dynamically and over usage/time.

FIG. 16A illustrates the block diagram of the cyber security module in view of the system and server according to an embodiment.

Referring to FIG. 16A, system 1600 comprising processor 1608 communication module 1612, cyber security module 1630, and information security management module 1632 in communication with server 1670, is shown. In an embodiment, FIG. 16A shows the block diagram of the cyber security module. The communication of data between the system 1600 and the server 1670 through the communication module 1612 is first verified by the information security management module 1632 before being transmitted from the system to the server or from the server to the system. The information security management module is operable to analyze the data for potential cyber security threats, to encrypt the data when no cyber security threat is detected, and to transmit the data encrypted to the system or the server.

FIG. 16B shows an embodiment of the cyber security module, in accordance with some embodiments of the present disclosure.

In an embodiment, the cyber security module further comprises an information security management module providing isolation between the system and the server. FIG. 16B shows the flowchart of securing the data through the cyber security module 1630. At step 1640, the information security management module is operable to receive data from the communication module. At step 1641, the information security management module exchanges a security key at a start of the communication between the communication module and the server. At step 1642, the information security management module receives a security key from the server. At step 1643, the information security management module authenticates an identity of the server by verifying the security key. At step 1644, the information security management module analyzes the security key for potential cyber security threats. At step 1645, the information security management module negotiates an encryption key between the communication module and the server. At step 1646, the information security management module receives the encrypted data. At step 1647, the information security management module transmits the encrypted data to the server when no cyber security threat is detected.

FIG. 16C shows another embodiment of the cyber security module, in accordance with some embodiments of the present disclosure.

In an embodiment, FIG. 16C shows the flowchart of securing the data through the cyber security module 1630. At step 1651, the information security management module is operable to: exchange a security key at a start of the communication between the communication module and the server. At step 1652, the information security management module receives a security key from the server. At step 1653, the information security management module authenticates an identity of the server by verifying the security key. At step 1654, the information security management module analyzes the security key for potential cyber security threats. At step 1655, the information security management module negotiates an encryption key between the communication module and the server. At step 1656, the information security management module receives encrypted data. At step 1657, the information security management module decrypts the encrypted data, and performs an integrity check of the decrypted data. At step 1658, the information security management module transmits the decrypted data to the communication module when no cyber security threat is detected.

In an embodiment, the integrity check is a hash-signature verification using a Secure Hash Algorithm 256 (SHA256) or a similar method.

In an embodiment, the information security management module is configured to perform asynchronous authentication and validation of the communication between the communication module and the server.

In an embodiment, the information security management module is configured to raise an alarm if a cyber security threat is detected. In an embodiment, the information security management module is configured to discard the encrypted data received if the integrity check of the encrypted data fails.

In an embodiment, the information security management module is configured to check the integrity of the decrypted data by checking accuracy, consistency, and any possible data loss during the communication through the communication module.

In an embodiment, the server is physically isolated from the system through the information security management module. When the system communicates with the server as shown in FIG. 16A, identity authentication is first carried out on the system and the server. The system is responsible for communicating/exchanging a public key of the system and a signature of the public key with the server. The public key of the system and the signature of the public key are sent to the information security management module. The information security management module decrypts the signature and verifies whether the decrypted public key is consistent with the received original public key or not. If the decrypted public key is verified, the identity authentication is passed. Similarly, the system and the server carry out identity authentication on the information security management module. After the identity authentication is passed on to the information security management module, the two communication parties, the system, and the server, negotiate an encryption key and an integrity check key for data communication of the two communication parties through the authenticated asymmetric key. A session ID number is transmitted in the identity authentication process, so that the key needs to be bound with the session ID number; when the system sends data to the outside, the information security gateway receives the data through the communication module, performs integrity authentication on the data, then encrypts the data through a negotiated secret key, and finally transmits the data to the server through the communication module. When the information security management module receives data through the communication module, the data is decrypted first, integrity verification is carried out on the data after decryption, and if verification is passed, the data is sent out through the communication module; otherwise, the data is discarded.

In an embodiment, the identity authentication is realized by adopting an asymmetric key with a signature.

In an embodiment, the signature is realized by a pair of asymmetric keys which are trusted by the information security management module and the system, wherein the private key is used for signing the identities of the two communication parties, and the public key is used for verifying that the identities of the two communication parties are signed. Signing identity comprises a public and a private key pair. Signing identity is referred to as the common name of certificates.

In an embodiment, both communication parties need to authenticate their own identities through a pair of asymmetric keys, and a task in charge of communication with the information security management module of the system is identified by a unique pair of asymmetric keys.

In an embodiment, the dynamic negotiation key is encrypted by adopting an Rivest-Shamir-Adleman (RSA) encryption algorithm. RSA is a public-key cryptosystem that is widely used for secure data transmission. The negotiated keys include a data encryption key and a data integrity check key.

In an embodiment, the data encryption method is a Triple Data Encryption Algorithm (3DES) encryption algorithm. The integrity check algorithm is a Hash-based Message Authentication Code (HMAC-MD5-128) algorithm. When data is output, the integrity check calculation is carried out on the data, the calculated Message Authentication Code (MAC) value is added with the header of the value data message, then the data (including the MAC of the header) is encrypted by using a 3DES algorithm, the header information of a security layer is added after the data is encrypted, and then the data is sent to the next layer for processing. In an embodiment the next layer refers to a transport layer in the Transmission Control Protocol/Internet Protocol (TCP/IP) model.

The information security management module ensures the safety, reliability, and confidentiality of the communication between the system and the server through the identity authentication when the communication between the two communication parties starts the data encryption and the data integrity authentication. The method is particularly suitable for an embedded platform which has less resources and is not connected with a Public Key Infrastructure (PKI) system and can ensure that the safety of the data on the server cannot be compromised by a hacker attack under the condition of the Internet by ensuring the safety and reliability of the communication between the system and the server.

The descriptions of the one or more embodiments are for purposes of illustration but are not exhaustive or limiting to the embodiments described herein. Many modifications and variations will be apparent to those of ordinary skill in the art without departing from the scope and spirit of the described embodiments. The terminology used herein best explains the principles of the embodiments, the practical application and/or technical improvement over technologies found in the marketplace, and/or to enable others of ordinary skill in the art to understand the embodiments described herein.

1-51. (canceled)

52. A system comprising:
a communication module; and
a processor storing instructions in a non-transitory memory that, when executed, cause the processor to:
identify an item mechanically coupled to a vehicle;
establish a first connection, via the communication module, with the item;
generate a test pattern for testing a device from a plurality of devices, wherein the device is at least one of part of the vehicle, and part of the item;
determine control of the device; and
actuate the device to verify a functionality of the device based on the test pattern.

53. The system of claim 52, wherein the item comprises at least one of a trailer, a rack, a recreational vehicle, a stock trailer, a boat trailer, and a cargo carrier.

54. The system of claim 52, wherein the processor is further configured to:
update the test pattern to verify the functionality of each of the plurality of devices individually; and
actuate each of the devices based on the test pattern.

55. The system of claim 52, wherein the device is configured to provide information regarding at least one of a surrounding vehicle, and a surrounding area of the vehicle and the item.

56. The system of claim 52, wherein the device comprises at least one of an item sensor, an item light, an item signal, an item wiper, an item mirror, a vehicle sensor, a vehicle light, a vehicle signal, a vehicle wiper, a vehicle mirror, a radar-based sensor, a LAser Detection And Ranging (LADAR) sensor, a Light Detection and Ranging (LIDAR) sensor, a camera, an infrared camera, a night vision camera, and a thermal camera, a vision-based sensor, a light-based sensor, an infrared sensor, an optical sensor, a temperature sensor, a pressure sensor, a proximity sensor, a GPS sensor, an audio sensor, a stereo vision sensor, a headlight, a taillight, a turn indicator, a brake light, and a back light.

57. The system of claim 52, wherein the test pattern comprises at least one of a sequential test pattern, an overall test pattern, a selective test pattern, a detailed test pattern, a small test pattern, a speed based test pattern, and a priority based test pattern.

58. The system of claim 52, wherein the processor is further configured to:
transmit the test pattern to an external device; and
actuate the device of the item based on an instruction received from the external device.

59. The system of claim 58, wherein the external device comprises at least one of a key fob, a key card, a voice actuated device, a wearable device, and a mobile device.

60. The system of claim 58, wherein the processor is further configured to:
interpret an external device signal as actuating the device when the external device is in proximity to the device.

61. The system of claim 60, wherein the processor is further configured to:
update in real time a starting point of the test pattern based on the proximity of the external device from the device.

62. The system of claim 52, wherein the processor is further configured to:
transmit a result of actuation of the device to a display system; and
store the result in a database.

63. The system of claim 62, wherein the processor is further configured to:
retrieve the result from the database;
perform a historical analysis of a device performance based on the result; and
predict a malfunction of the device.

64. The system of claim 52, wherein the communication module supports a communication protocol, wherein the communication protocol comprises at least one of a Hypertext Transfer Protocol (HTTP), Message Queuing Telemetry Transport (MQTT), WebSocket, Constrained Application Protocol (CoAP) and Advanced Message Queuing Protocol (AMQP).

65. The system of claim 52, wherein the communication module comprises a V2X telematics communication module.

66. The system of claim 52, wherein the communication module is enabled for at least one of a vehicle-to-vehicle communication, vehicle-to-infrastructure communication, and vehicle-to-everything communication.

67. The system of claim 52, wherein the processor is further configured to:
generate a machine learning model; and
transmit the test pattern to the machine learning model; and
wherein the machine learning model is configured to: predict an optimized test pattern to actuate the device to verify the functionality of the device.

68. A method comprising:
determining an item mechanically coupled to a vehicle;
establishing a first connection via a communication module, with the item;
generating a test pattern for testing a device from a plurality of devices, wherein the device is at least one of part of the vehicle, and part of the item;
determining control of the device; and
actuating the device to verify a functionality of the device based on the test pattern.

69. The method of claim 68, further comprising:
updating in real time a starting point of the test pattern based on proximity of an external device from the device.

70. The method of claim 68, further comprising:
transmitting a result of the actuation of the device to a display system;
storing the result in a database;
retrieving the result from the database;
performing a historical analysis of a device performance based on the result; and
predicting a malfunction of the device.

71. A non-transitory computer-readable medium having stored thereon instructions executable by a computer system to perform operations comprising:
determining an item mechanically coupled to a vehicle;
establishing a first connection via a communication module, with the item;
generating a test pattern for testing a device from a plurality of devices, wherein the device is at least one of part of the vehicle, and part of the item;
determining control of the device; and
actuating the device to verify a functionality of the device based on the test pattern.
